(19) United States
(12) Patent Application Publication
(10) Pub. No.: US 2026/0215227 A1
(43) Pub. Date: Jul. 23, 2026

(54) SEMICONDUCTOR DIE ASSEMBLY AND METHOD OF MANUFACTURING THE SAME

(71) Applicant: TAIWAN SEMICONDUCTOR MANUFACTURING COMPANY LTD., HSINCHU (TW)

(72) Inventors: YU-CHI CHANG, KAOHSIUNG CITY (TW); HSIN-LI CHENG, HSINCHU COUNTY (TW); SHU-HUI SU, NEW TAIPEI CITY (TW); LI-FENG TENG, HSINCHU CITY (TW); YINGKIT FELIX TSUI, CUPERTINO, CA (US); SHIH-FEN HUANG, HSINCHU COUNTY (TW)

(21) Appl. No.: 19/214,077

(22) Filed: May 21, 2025

Related U.S. Application Data
(60) Provisional application No. 63/748,458, filed on Jan. 23, 2025.

(51) Int. Cl. H01L 21/66; H01L 23/00

(52) U.S. Cl. CPC H10P 74/203; H10P 74/273; H10W 80/312; H10W 80/327; H10W 90/792

(57) ABSTRACT

A semiconductor die assembly and method of manufacturing the same are provided. The method includes steps of receiving a first wafer comprising a first semiconductor device and a first interconnect structure disposed over and coupled to the first semiconductor device; forming a barrier liner on a portion of the first interconnect structure; forming a test pad on the barrier liner; performing a first test on the first semiconductor device through the test pad; forming a first bonding structure over the first interconnect structure; receiving a second wafer comprising a second semiconductor device and a second interconnect structure over and coupled to the second semiconductor device; forming a second bonding structure over the second interconnect structure; bonding the first wafer to the second wafer by connecting the first and second bonding structures to form a wafer assembly; and performing a second test on the wafer assembly.

### CROSS-REFERENCE TO RELATED APPLICATION

This application claims the benefit of U.S. Provisional Application No. 63/748,458, filed Jan. 23, 2025, the entire disclosure of which is incorporated by reference herein.

### BACKGROUND

As integrated circuit technologies continue to advance, ongoing efforts are being made to increase performance and density, improve form factor, and reduce costs. One approach explored by designers to realize such benefits is the implementation of stacked three-dimensional (3D) integrated circuits. Some areas where 3D integrated circuits are suitable for consideration include stacking of two or more chips that are fabricated using different fabrication processes, or stacking of chips that are fabricated using same fabrication processes to reduce a footprint of the integrated circuit apparatus.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a flowchart of a method of manufacturing a semiconductor die assembly, in accordance with some embodiments of the present disclosure.

FIG. 2 is a top view of an intermediate stage of the method of manufacturing a semiconductor die assembly, in accordance with some embodiments of the present disclosure.

FIGS. 3, 4, 5, 6, 7, 8, 9, 10, 11, 12, 13, 14 and 15 are cross-sectional views of intermediate stages of the method of manufacturing a semiconductor die assembly, in accordance with some embodiments of the present disclosure.

FIG. 16 is a top view of an intermediate stage of the method of manufacturing a semiconductor die assembly, in accordance with some embodiments of the present disclosure.

FIGS. 17, 18, 19A and 19B are cross-sectional views of intermediate stages of the method of manufacturing a semiconductor die assembly, in accordance with some embodiments of the present disclosure.

FIG. 20 is a flowchart of a method of manufacturing a semiconductor die assembly, in accordance with some embodiments of the present disclosure.

FIGS. 21 and 22 are cross-sectional views of intermediate stages of the method of manufacturing a semiconductor die assembly, in accordance with some embodiments of the present disclosure.

FIG. 23 is a flowchart of a method of manufacturing a semiconductor die assembly, in accordance with some embodiments of the present disclosure.

FIGS. 24 and 25 are cross-sectional views of intermediate stages of the method of manufacturing a semiconductor die assembly, in accordance with some embodiments of the present disclosure.

FIG. 26 is a flowchart of a method of manufacturing a semiconductor die assembly, in accordance with some embodiments of the present disclosure.

FIGS. 27 and 28 are cross-sectional views of intermediate stages of the method of manufacturing a semiconductor die assembly, in accordance with some embodiments of the present disclosure.

FIG. 29 is a flowchart of a method of manufacturing a semiconductor die assembly, in accordance with some embodiments of the present disclosure.

FIGS. 30 and 31 are cross-sectional views of intermediate stages of the method of manufacturing a semiconductor die assembly, in accordance with some embodiments of the present disclosure.

FIG. 32 is a flowchart of a method of manufacturing a semiconductor die assembly, in accordance with some embodiments of the present disclosure.

FIGS. 33 to 36 are cross-sectional views of intermediate stages of the method of manufacturing a semiconductor die assembly, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In the current process for fabricating a bonded wafer structure, such as a wafer-on-wafer structure, functional performance of individual wafers is generally not known prior to bonding of the wafers. Circuit probe testing, for example, may only be performed after the wafers have been bonded to one another to form a bonded wafer structure and contact pads have been formed on the bonded wafer structure. However, if one of the wafers used to form the bonded wafer structure is defective, then the entire bonded wafer structure may also be defective, and may need to be discarded. This may significantly lower productivity and increase costs associated with the fabrication of the bonded wafer structures.

Accordingly, there is a need for bonded wafer structures, and methods of fabricating bonded wafer structures, that enable improved testing of individual wafers before the wafers are bonded to one another to form a bonded wafer structure. Various embodiments disclosed herein include forming one or more contact pads over an interconnect structure of a wafer prior to bonding the wafer to another wafer to form a bonded wafer structure. The presence of such contact pads makes it possible to perform comprehensive testing, including circuit probe testing, on individual wafers prior to forming the bonded wafer structure. Such testing enables earlier identification of defective wafers, resulting in improved yields and lower costs for fabrication of bonded wafer structures.

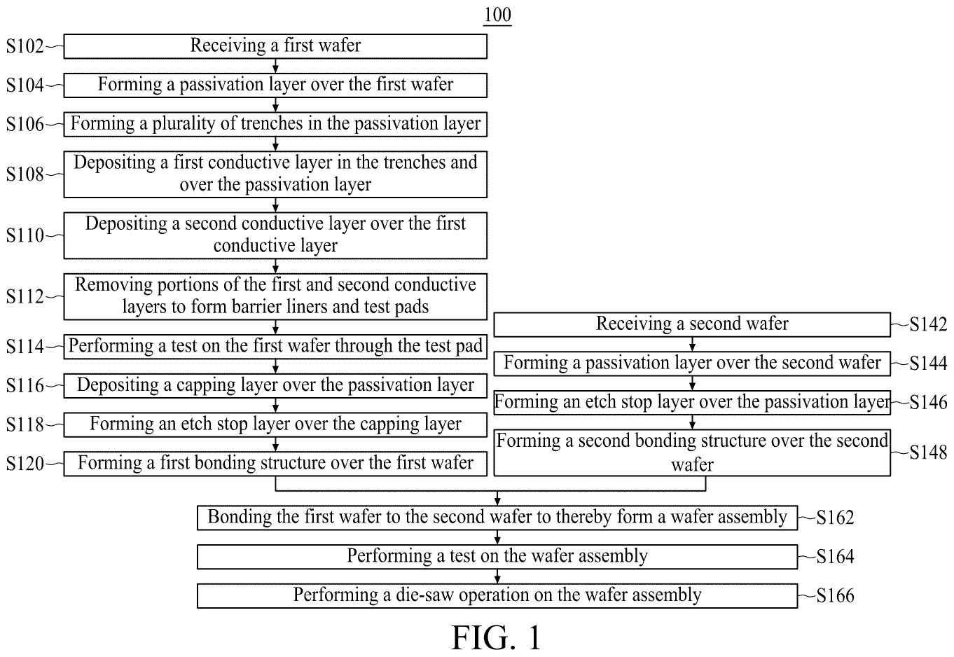

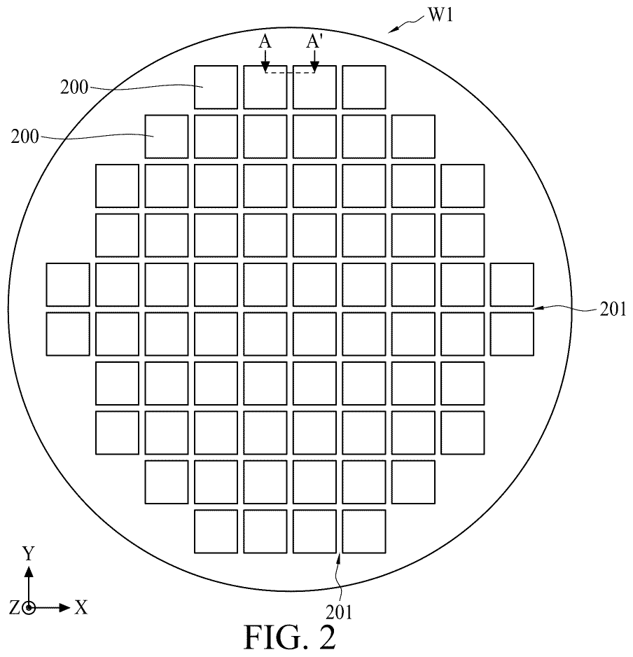

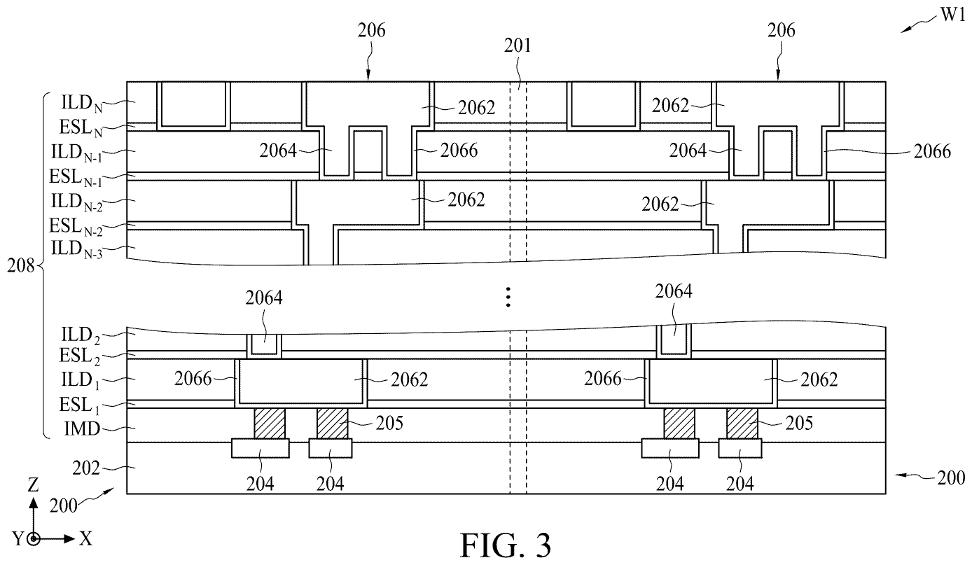

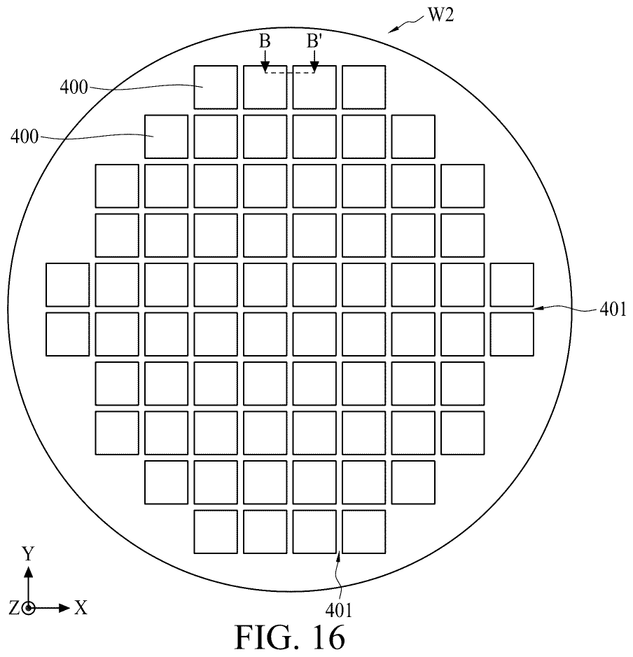

FIG. 1 is a flowchart of a method 100 of manufacturing a semiconductor die assembly 10, in accordance with some embodiments of the present disclosure. FIGS. 2 and 16 are top views of an intermediate stage of the method 100 of manufacturing a semiconductor die assembly 10, in accordance with some embodiments of the present disclosure. FIGS. 3 to 15 and 17 to 19B are cross-sectional views of intermediate stages of the method 100 of manufacturing the semiconductor die assembly 10, in accordance with some embodiments of the present disclosure. In the following description, the manufacturing stages shown in FIGS. 2 to 19B are discussed with reference to the process steps shown in FIG. 1. It should be understood that additional steps can be provided before, during, and after the steps shown in FIG. 1, and some of the steps described below can be replaced or eliminated, for additional embodiments of the method 100. The order of the steps may be changed.

Referring to FIG. 2, a first wafer W1 is received in accordance with step S102 in FIG. 1. In some embodiments, the first wafer W1 includes multiple first semiconductor dies 200 arranged in columns and rows. The first semiconductor dies 200 are spaced apart from each other by scribe streets 201, which are to be sawed to separate the first semiconductor dies 200 from each other in a subsequent die-saw operation. The first semiconductor dies 200 may include any type of integrated circuit, such as a processor, a logic circuit, a memory circuit, an analog circuit, a digital circuit, a mixed-signal circuit, or the like.

FIG. 3 is a cross-sectional view of a part of the first wafer W1. In some embodiments, FIG. 3 is a cross-sectional view taken along line A-A′ of FIG. 2. In some embodiments, each of the first semiconductor dies 200 includes a substrate 202, various semiconductor devices 204 and a first interconnect structure 206. The substrate 202 may be a semiconductor substrate comprising silicon, germanium, gallium arsenide, silicon carbon, or another semiconductor material used in semiconductor device processing. However, the disclosure is not limited thereto, and other suitable materials may be used to form the substrate 202. The semiconductor devices 204 may be disposed in and/or on the substrate 202. The semiconductor devices 204 may include active devices (e.g., transistors, diodes, etc.), passive devices (e.g., resistors, capacitors, inductors, etc.), or combinations thereof. The semiconductor devices 204 may be formed in and/or on the substrate 202 in a front-end-of-line (FEOL) stage.

The first interconnect structure 206 may be disposed over the substrate 202 and the semiconductor device 204. In some embodiments, the first interconnect structure 206 electrically connects the semiconductor devices 204 to form the integrated circuit. In some embodiments, the first interconnect structure 206 includes a plurality of conductive lines 2062 and a plurality of conductive vias 2064 stacked in an alternating manner. The conductive lines 2062 and the conductive vias 2064 may include metal, such as copper (Cu), aluminum (Al), an aluminum-copper alloy, or the like.

In some embodiments, the conductive lines 2062 and the conductive vias 2064 are laterally surrounded by one or more dielectric layers, such as inter-metal layer IMD, inter-layer dielectric layers ILD₁ to ILD_{N} and etch stop layers ESL₁ to ESL_{N}, where N is an integer. In some embodiments, the inter-layer dielectric layers ILD₁ to ILD_{N} and the etch stop layers ESL₁ to ESL_{N} are stacked in an alternating manner. The inter-metal layer IMD is disposed between the etch sop layer ESL₁ and the substrate 202 and between the etch sop layer ESL₁ and the semiconductor device 204. The conductive lines 2062 may extend horizontally in an X direction and in a Y-direction perpendicular to the X-direction. The conductive vias 2064 may extend vertically (i.e., in a Z-direction) to provide electrical connections between the conductive lines 2062 in two adjacent inter-layer dielectric layers ILD₁ to ILD_{N}. For example, a conductive via 2064 allows a conductive line 2062 in the inter-layer dielectric layer ILD_{N-2} to be electrically connected to another conductive line 2062 in the inter-layer dielectric layer ILD_{N}.

In some embodiments, the inter-layer dielectric layers ILD₁ to ILD_{N} and the etch stop layers ESL₁ to ESL_{N} comprise different dielectric materials. The etch stop layers ESL₁ to ESL_{N} are formed of a dielectric material having an etch selectivity different from the etch selectivities of adjacent inter-layer dielectric layers ILD₁ to ILD_{N}. For example, The material of the inter-layer dielectric layers ILD₁ to ILD_{N} may be selected to have a high etching selectivity with respect to a certain etchant relative to the etch stop layers ESL₁ to ESL_{N}. For example, in some embodiments, the inter-layer dielectric layers ILD₁ to ILD_{N} include oxide, and the etch stop layers ESL₁ to ESL_{N} include nitride. The inter-metal layer IMD, the inter-layer dielectric layers ILD₁ to ILD_{N} and the etch stop layers ESL₁ to ESL_{N} may be collectively referred to as a dielectric stack 208.

In some embodiments, the first interconnect structure 206 further includes conductive liners 2066 between the conductive lines 2062 and the inter-layer dielectric layers ILD₁ to ILD_{N}, between the conductive lines 2062 and the etch stop layers ESL₁ to ESL_{N}, between the conductive vias 2064 and the inter-layer dielectric layers ILD₁ to ILD_{N}, and between the conductive vias 2064 and the etch stop layers ESL₁ to ESL_{N}. The conductive liner 2066 may be formed of titanium (Ti), titanium nitride (TiN), tantalum (Ta), tantalum nitride (TaN), or the like. The conductive liner 2066 may serve to adhere the conductive lines 2062 and the conductive vias 2064 to the dielectric layers ILD₁ to ILD_{N} and the etch stop layers ESL₁ to ESL_{N}. The conductive liner 2066 may also prevent metal in the conductive lines 2062 and the conductive vias 2064 from diffusing into neighboring dielectric layers ILD₁ to ILD_{N} and neighboring etch stop layers ESL₁ to ESL_{N}. The first interconnect structure 206, the dielectric layers ILD₁ to ILD_{N} and the etch stop layers ESL₁ to ESL_{N} may be formed over the substrate 202 and the semiconductor device 204 in a back-end-of-line (BEOL) stage.

In some embodiments, the first semiconductor die 200 further includes one or more contact plugs 205 used for connecting the semiconductor devices 204 to the first interconnect structure 206. The contact plugs 205 are disposed between the semiconductor devices 204 and the first interconnect structure 206 and laterally surrounded by the inter-metal layer IMD. The contact plugs 205 may include metal such as tungsten (W) or the like. The dielectric stack 208 may cover the substrate 202 and the semiconductor devices 204 and laterally surround the contact plug 205 and the first interconnect structure 206.

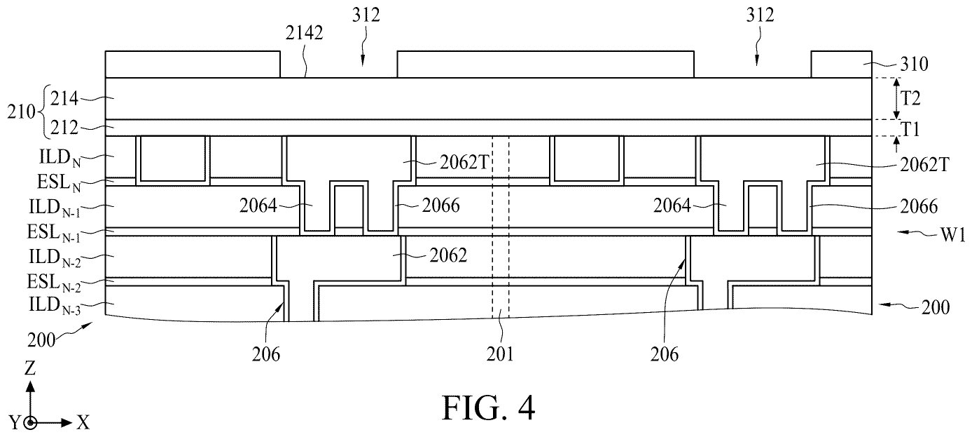

Referring to FIG. 4, a passivation layer 210 is deposited over the first wafer W1 in accordance with step S104 in FIG. 1. In some embodiments, the passivation layer 210 is deposited over the first interconnect structure 206 and the dielectric stack 208. The passivation layer 210 may be in contact with a topmost inter-layer dielectric layer ILD_{N} and a topmost conductive line 2062T. Referring to FIGS. 3 and 4, the topmost inter-layer dielectric layer ILD_{N} may be a dielectric layer of the dielectric stack 208 farthest from the substrate 200 and/or the semiconductor devices 204. The topmost conductive line 2062T may be a conductive line of the first interconnect structure 206 farthest from the substrate 200 and/or the semiconductor devices 204 shown in FIG. 3.

Referring to FIG. 4, the passivation layer 210 may be a single-layer structure or a multilayer structure. In some embodiments, the passivation layer 210 includes two layers, such as a bottom layer 212 and a top layer 214. The bottom layer 212 is disposed between the top layer 214 and the topmost conductive line 2062T and between the top layer 214 and the topmost inter-layer dielectric layer ILD_{N}. However, the present disclosure is not limited thereto, and the passivation layer 210 may include more than two layers.

In some embodiments, the bottom layer 212 and the top layer 214 include different dielectric materials. For example, in some embodiments, the bottom layer 212 includes nitride and the top layer 214 includes oxide. The bottom layer 212 has a thickness T1. The top layer 214 may have a thickness T2 greater than the thickness T1 of the bottom layer 212. The bottom layer 212 and the top layer 214 may be respectively formed by, for example, sputtering, chemical vapor deposition (CVD), physical vapor deposition (PVD), atomic layer deposition (ALD), spin-coating, a combination thereof, or other suitable techniques.

After the deposition of the passivation layer 210, a patterned mask layer 310 is formed on the top layer 214. The patterned mask layer 310 may include an opening 312 to expose a portion of an upper surface 2142 of the top layer 214. The formation of the patterned mask layer 310 may include forming a mask layer and a blanket photoresist layer on the top layer 214 and patterning the blanket photoresist layer. A pattern of the photoresist layer is then transferred to the mask layer, thereby forming the patterned mask layer 310.

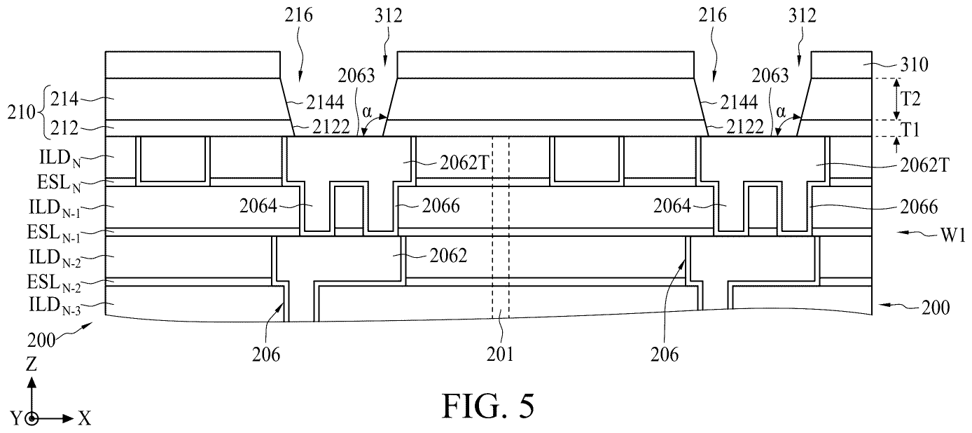

Referring to FIG. 5, a plurality of trenches 216 are formed in the passivation layer 210 in accordance with step S106 in FIG. 1. The trenches 216 penetrate the passivation layer 210 and are formed by one or more etching operations, using the patterned mask layer 310 as an etch mask. At least a portion of the topmost conductive line 2062T in each first semiconductor die 200 is exposed through the trench 216. During the etching operation(s), the top layer 214 and the bottom layer 212 are sequentially etched to form the trench 216. The etching operation(s) may include a wet etch, a dry etch, a combination thereof, or the like.

After the etching operation(s), the bottom layer 212 includes a sidewall 2122 exposed through the trench 216, wherein an angle α between the sidewall 2122 and an upper surface 2063 of the topmost conductive line 2062T may be equal to or greater than 90 degrees. In addition, after the etching operation(s), the top layer 214 may include a sidewall 2144 exposed through the trench 216 and connected to the sidewall 2122 of the bottom layer 212. After the formation of the trench 216, the patterned mask layer 310 is removed using a suitable operation.

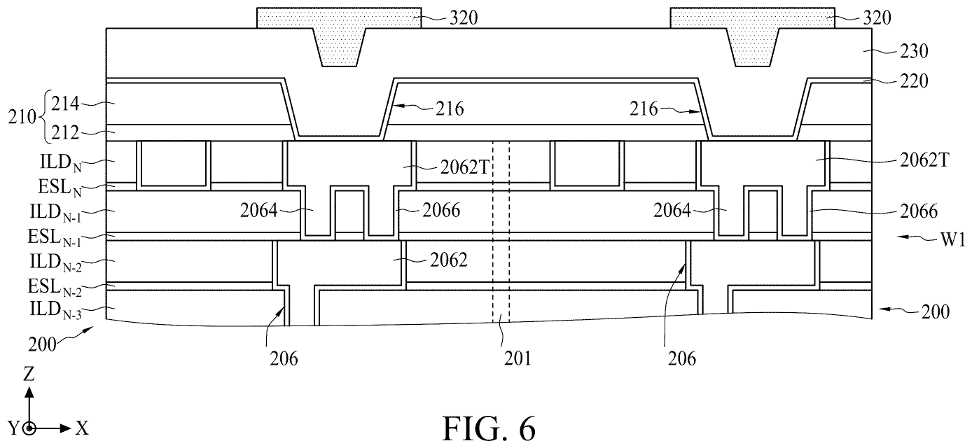

Referring to FIG. 6, a first conductive layer 220 is deposited in the trenches 216 and over the top layer 214 in accordance with step S108 in FIG. 1. The first conductive layer 220 may be conformal to the upper surface 2142 and the sidewall 2144 of the top layer 214, the sidewall 2122 of the bottom layer 212, and the upper surface 2063 of the topmost conductive line 2062T exposed through the trench 216. The first conductive layer 220 may include titanium, titanium nitride, tantalum, tantalum nitride, or another suitable conductive material. The first conductive layer 220 may be formed by, for example, PVD, CVA, ALD or another suitable technique.

Still referring to FIG. 6, a second conductive layer 230 is deposited on the first conductive layer 220 in accordance with step S110 in FIG. 1. In some embodiments, the second conductive layer 230 is conformal to the first conductive layer 220. The second conductive layer 230 may include aluminum, copper, aluminum alloy, copper alloy, or the like. The second conductive layer 230 may be formed by, for example, sputtering, CVD, PVD, ALD, or another suitable technique. The first conductive layer 220 may, for example, serve as an oxygen barrier to prevent oxygen in the passivation layer 210 from reaching and oxidizing the second conductive layer 230.

Subsequently, a patterned mask layer 320 is formed on portions of the second conductive layer 230. In some embodiments, each of the patterned mask layers 320 vertically overlaps one of the trenches 216. The patterned mask layer 320 may further overlap portions of the passivation layer 210 around the trenches 216. The formation of the patterned mask layer 320 may be essentially same as the formation of the patterned mask layer 310. The patterned mask layer 320 may be used to pattern the first and second conductive layers 220 and 230. The patterned mask layer 320 may overlap portions of the topmost interconnect line 2062T of the first interconnect structure 206.

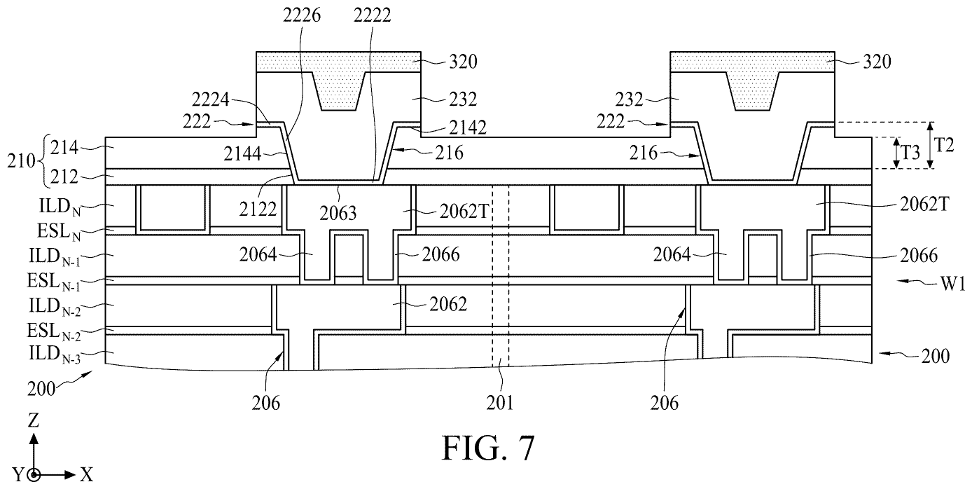

Referring to FIG. 7, portion of the first and second conductive layers 220 and 230 are removed to form barrier liners 222 and test pads 232 in accordance with step S112 in FIG. 1. The barrier liners 222 and the test pads 232 may be formed by one or more etching operations, using the patterned mask layer 320 as an etch mask. In some embodiments, the etching operations are performed to sequentially remove portions of the second conductive layer 230 and the first conductive layer 220 which are not covered by the patterned mask layer 320. The removed portions of the first and second conductive layers 220 and 230 are offset from portions of the topmost conductive lines 2062T exposed through the trenches 216.

According to some embodiments, as shown in FIG. 7, each barrier liner 222 includes a center section 2222, a peripheral section 2224 and an intermediate section 2226. The center section 2222, for example, is disposed in the trench 216 and in contact with the topmost conductive line 2062T. The peripheral section 2224 may be disposed on the upper surface 2142 of the top layer 214. The intermediate section 2226, for example, is disposed in the trench 216 and connects the center section 2222 to the peripheral section 2224. The intermediate section 2226 may be conformal to the sidewall 2122 of the bottom layer 212 and the sidewall 2144 of the top layer 214.

The top layer 214 may be partially removed during the patterning of the first and second conductive layers 220 and 230. Accordingly, after the etching operations, the top layer 214 has a non-uniform thickness. In some embodiments, portions of the top layer 214 exposed by the patterned mask layer 320 are removed during the formation of the barrier liner 222 and the test pad 232. After the etching operations, portions of the top layer 214 beneath the barrier liner 222 and the test pad 232 have the thickness T2, and remaining portions of the top layer 214 exposed through the barrier liner 222 and the test pad 232 have a thickness T3 less than the thickness T2. The top layer 214 may at least partially and laterally surround the barrier liners 222 and the test pads 232. After the formation of the barrier liners 222 and the test pads 232, the patterned mask layer 320 is removed using a suitable operation.

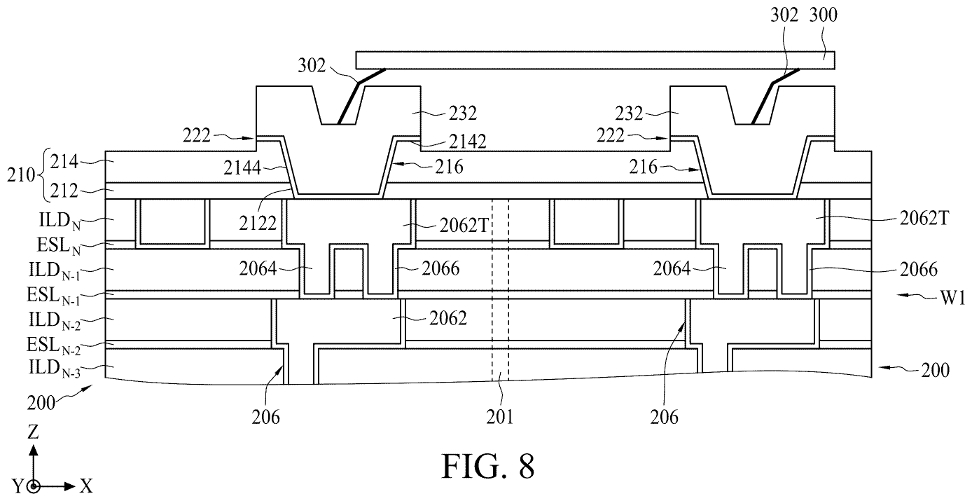

Referring to FIG. 8, a test is performed on the first semiconductor die 200 through the test pad 232 in accordance with step S114. The test may be performed to determine functionality of the first semiconductor die 200. In some embodiments, the test is performed by coupling the first semiconductor die 200 to a testing apparatus 300 through the test pads 232. The testing apparatus 300 includes a plurality of testing probes 302. The testing apparatus 300 may be physically and electrically coupled to each first semiconductor die 200 through one of the testing probes 302. In some embodiments, the testing probes 300 are arranged in columns and rows for testing all of the first semiconductor dies 200 on an entire first wafer W1 at one time in parallel for efficiency and to minimize testing time.

The test apparatus 300 may be operable to perform one or more wafer-level tests to determine performance and reliability of the first semiconductor die 200 on the first wafer W1 under various conditions. The wafer-level tests may include an acceptance test, a characterization test, a burn-in/stress test, and the like. The test apparatus 300 may be configured to generate test signals to be sent to the first semiconductor die 200 and to collect testing results from the first semiconductor die 200. Each testing probe 302 is used for transmitting the test signals to the corresponding test pad 232 and receiving the testing results from the corresponding test pad 232. The test apparatus 300 may further be configured to analyze the test results and identify good dies and defective dies. In some embodiments, a first semiconductor die 200 that successfully meets a test specification is identified as a known good die. On the other hand, a first semiconductor die 200 that fails to meet the test specification is determined to be a defective die. The test specification may include conditions and sequences of testing and acceptable ranges of parameters. The defective die may be marked to be excluded from a packaging operation after the subsequent die-saw operation. Thus, packaging costs can be saved.

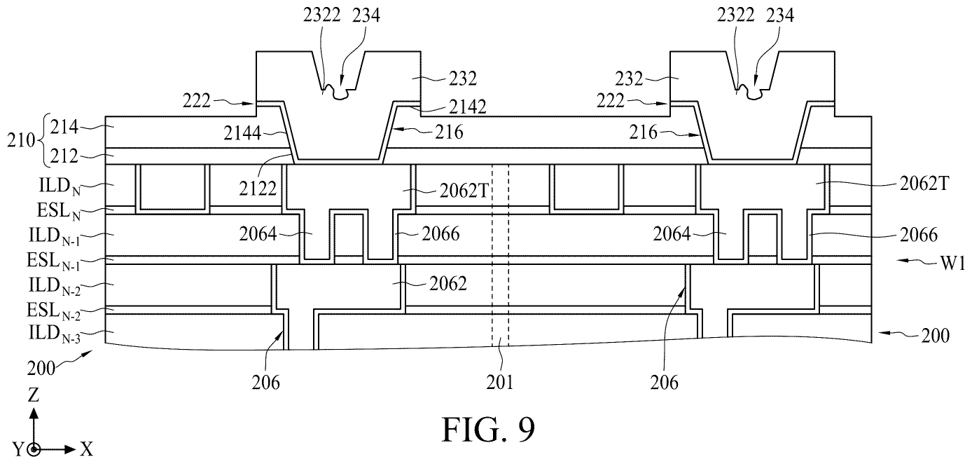

The testing probes 302 have sufficient rigidity for preventing substantial deformation or movement during the test, thereby avoiding test failure. During the test, the testing probe 302 may press or squeeze the test pad 232 to electrically connect to the first semiconductor die 200, which may cause damage to the test pad 232. According to some embodiments, as shown in FIG. 9, a probe mark 234 is left on a test area of the test pad 232 after the test is performed. The probe mark 234 may include one or more recesses extending inward from a boundary of the test pad 232 shown in FIG. 8. The probe mark 234 may further include one or more protrusions extending outward from the boundary of the test pad 232 shown in FIG. 8. The test pad 232 including the probe mark 234 may have a non-smooth and roughened upper surface 2322 over the center section 2222 of the barrier liner 222.

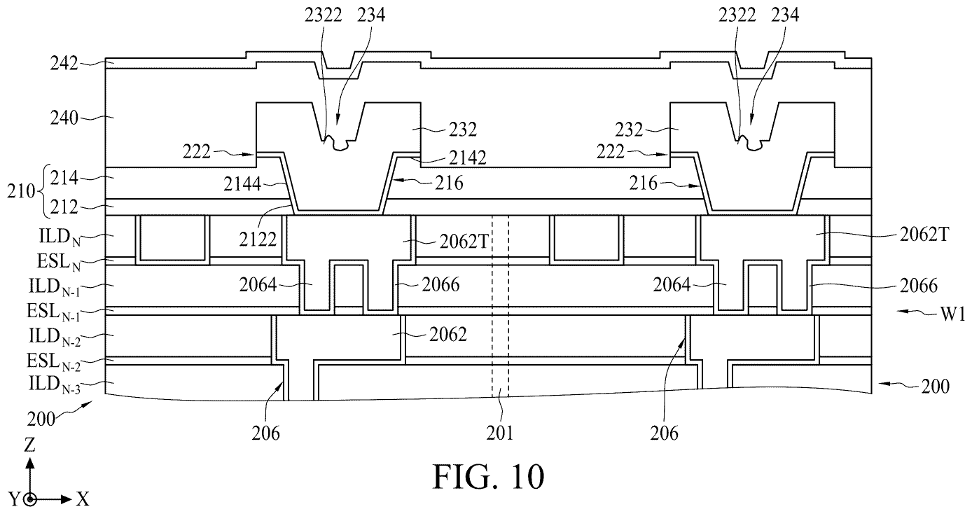

Referring to FIG. 10, a capping layer 240 is deposited over the passivation layer 210 in accordance with step S116 in FIG. 1. The capping layer 240 is deposited on the top layer 214 and the test pads 232. In some embodiments, the capping layer 240 is conformal to the top layer 214, the barrier liners 222 and the test pads 232. An interface between the capping layer 240 and the top layer 214 is lower than an interface of between barrier liner 222 and the top layer 214. The capping layer 240 may include a material same as a material of the top layer 214. For example, the capping layer 240 includes oxide. The capping layer 240 may be formed by any suitable method, such as CVD, plasma-enhanced CVD (PECVD), a spin-coating operation, a combination thereof, or the like.

Subsequently, an etch stop layer 242 is deposited on the capping layer 240 in accordance with step S118 in FIG. 1. The etch stop layer 242 may be conformal to the capping layer 240. In some embodiments, the etch stop layer 242 is formed of a dielectric material having an etch selectivity different from etch selectivities of adjacent layers, e.g., the capping layer 240. For example, in some embodiments, the etch stop layer 242 includes silicon nitride. However, the disclosure is not limited thereto, and other suitable materials may be used to form the etch stop layer 242. The etch stop layer 242 may be deposited by, for example, CVD, PECVD, the like, or a combination thereof.

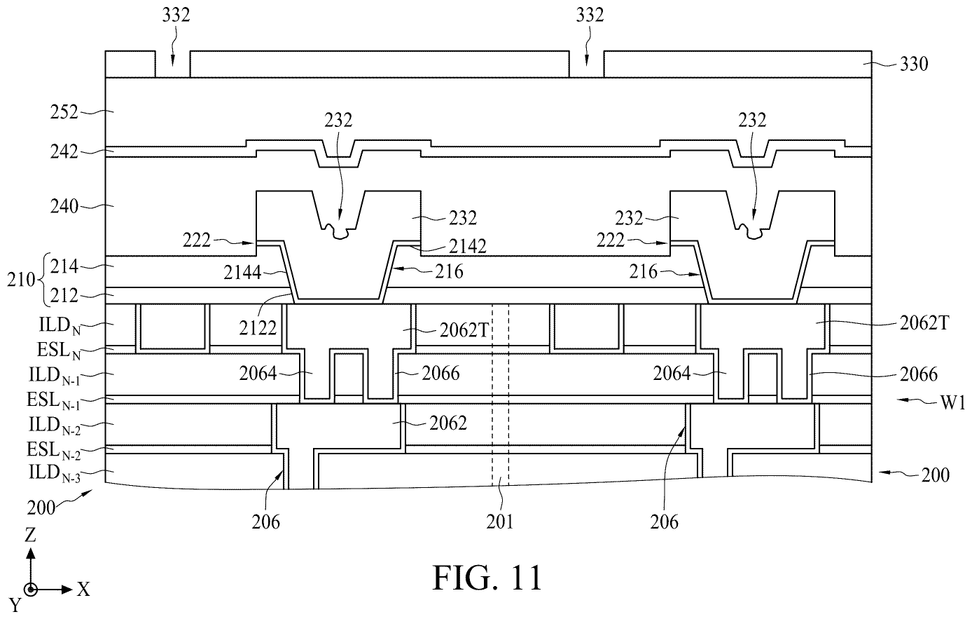

Referring to FIGS. 11 to 15, a first bonding structure 250 is formed over the first wafer W1 in accordance with step S120 in FIG. 1. In some embodiments, the first bonding structure 250 is disposed over the first interconnect structure 206. The first bonding structure 250 may be electrically coupled to the first interconnect structure 206. The first bonding structure 250 may be disposed at a front side of the first wafer W1. The front side of the first wafer W1 is where the semiconductor device 204 is fabricated.

Referring to FIG. 11, a bonding dielectric layer 252 is deposited over the etch stop layer 252. In some embodiments, the bonding dielectric layer 252 is formed of a dielectric material having an etch selectivity different from the etch selectivity of the etch stop layer 242. The bonding dielectric layer 252 may include, for example but not limited thereto, oxide. The bonding dielectric layer 252 may be deposited using CVD, ALD, or another deposition technique. In some embodiments, a planarization operation is performed on the bonding dielectric layer 252. After the planarization operation, the bonding dielectric layer 252 may have a substantially flat top surface. The planarization operation may include a chemical-mechanical polishing (CMP).

Subsequently, a patterned mask layer 330 is formed on at least a portion of the bonding dielectric layer 252. The formation of the patterned mask layer 330 may be essentially same as the formation of the patterned mask layer 310. In some embodiments, the patterned mask layer 330 includes at least one opening 332 in each first semiconductor die 200. The opening 332 may be disposed above a portion of the topmost conductive line 2062T not covered by the barrier liner 222 and the test pad 232.

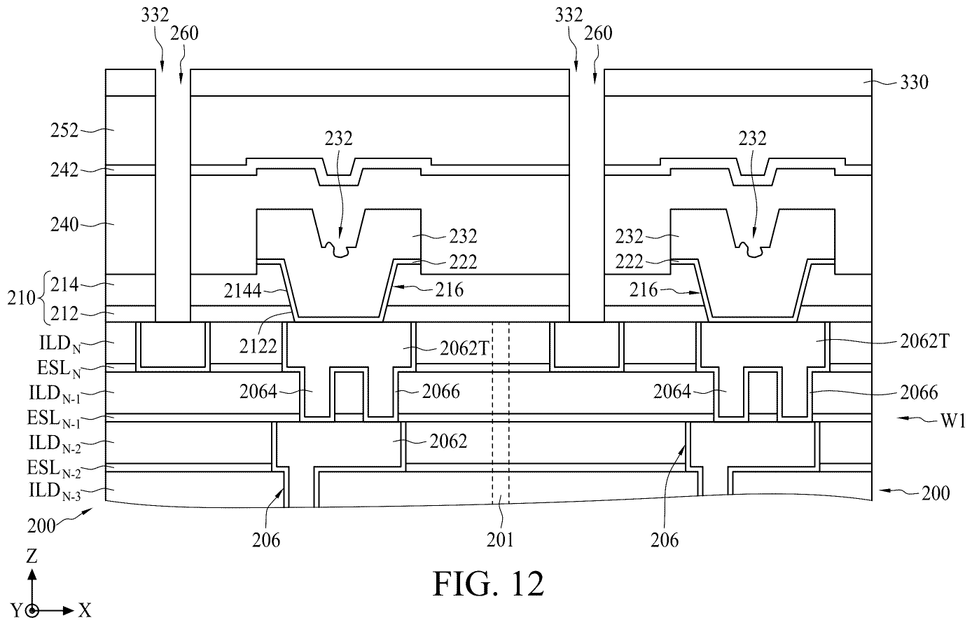

Referring to FIG. 12, one or more etching operations are performed to etch the bonding dielectric layer 252, the etch stop layer 242, the capping layer 240 and the passivation layer 210 through the openings 332, so that via-holes 260 are formed to expose the portions of the topmost conductive line 2062T. The etching operations may include a wet etch, a dry etch, a combination thereof, or the like. After the formation of the via-holes 260, the patterned mask layer 330 is removed using suitable operations.

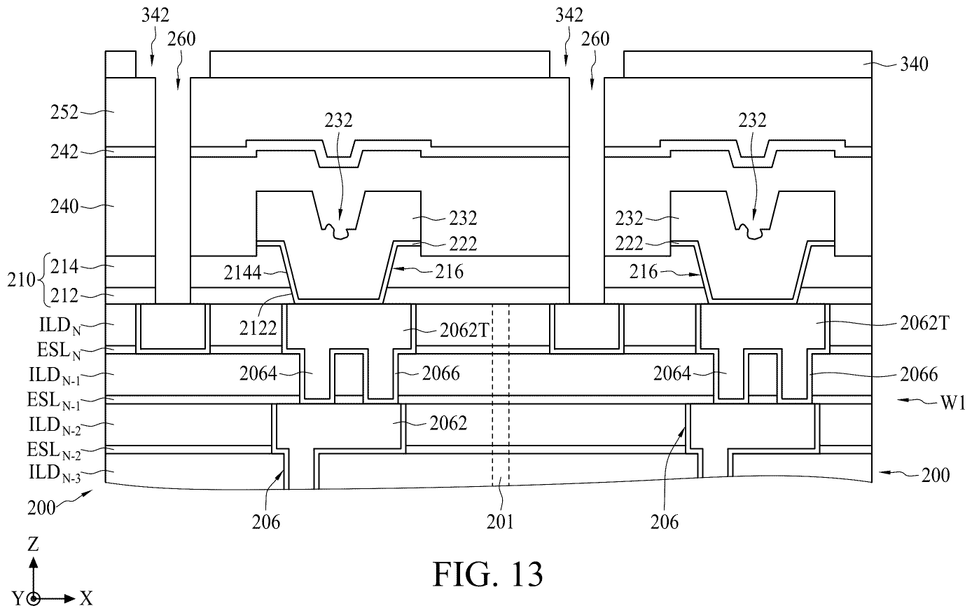

Referring to FIG. 13, a patterned mask layer 340 is formed on at least a portion of the bonding dielectric layer 252. The formation of the patterned mask layer 340 may be essentially same as the formation of the patterned mask layer 320. The patterned mask layer 340 may include multiple openings 342 respectively connected to the via-holes 260.

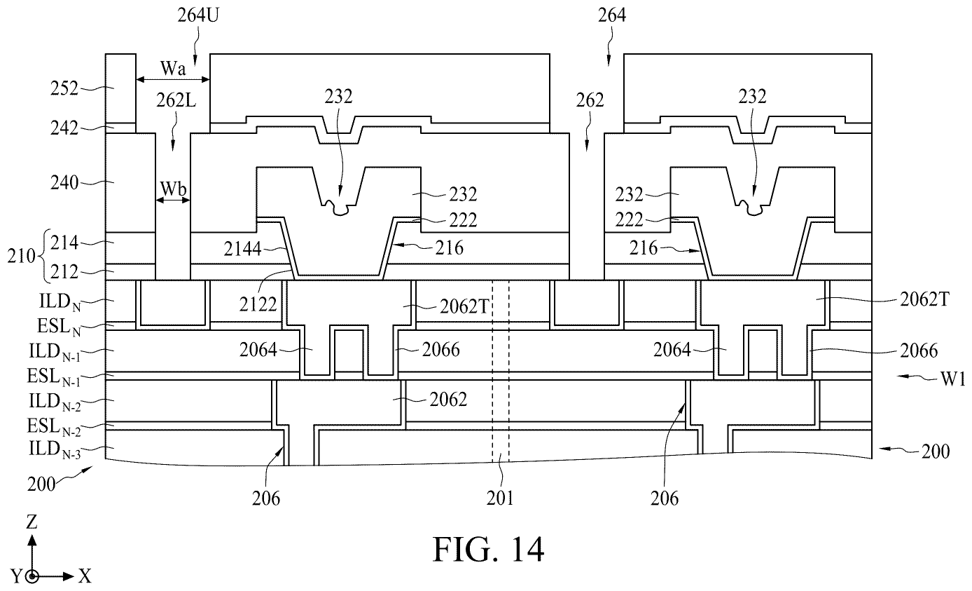

Referring to FIGS. 13 and 14, the etch stop layer 242 and the bonding dielectric layer 252 are etched through the openings 342, so that via-trenches 260 are formed. Each of the via-trenches 260 may include an upper trench 264U and a lower via-hole 262L connected to each other. In some embodiments, the upper trenches 264U are laterally surrounded or defined by the etch stop layer 242 and the bonding dielectric layer 252, and the lower via-holes 262L are laterally surrounded or defined by the passivation layer 210 and the capping layer 240. The upper trench 264U has a width Wa. The lower via-hole 262L may have a width Wb less than the width Wa of the upper trench 264U. In some embodiments, the via-trenches 260 are formed using a dual damascene process, and the dual damascene process is, for example, a via-first-trench-last approach. However, the present disclosure is not limited thereto, and the via trenches 260 may be formed using a trench-first-via-last approach. After the formation of the via-trenches 260, the patterned mask layer 340 is removed using suitable operations.

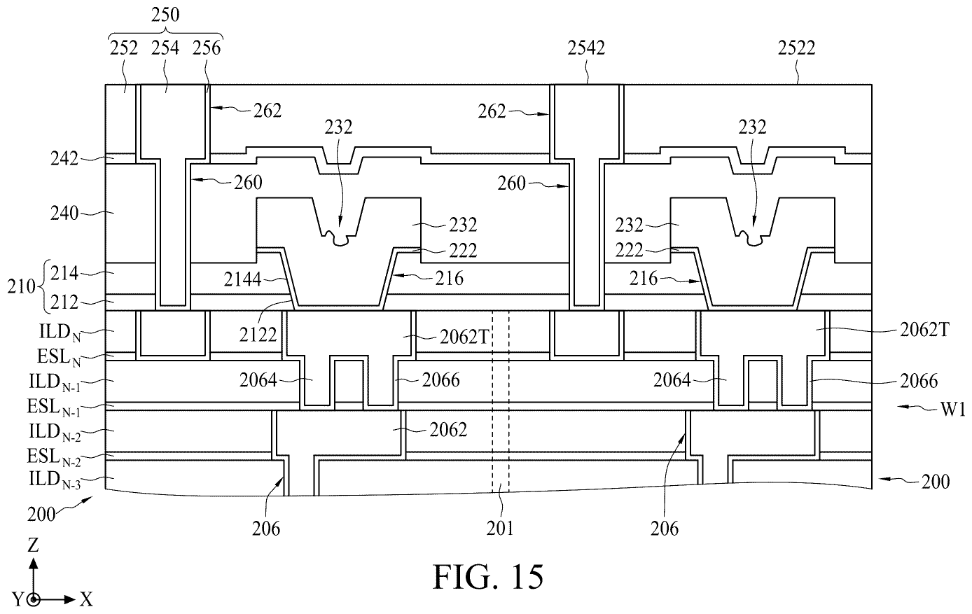

Referring to FIG. 15, bonding interconnect structures 254 are formed in the via-trenches 260. Accordingly, the first bonding structure 250 is completely formed. The first bonding structure 250 may include the bonding dielectric layer 252 and the bonding interconnect structures 254 at least laterally surrounded by the bonding dielectric layer 252. Each bonding interconnect structure 254 may further be electrically coupled to the underlying first semiconductor die 200. In some embodiments, each bonding interconnect structure 254 penetrates the bonding dielectric layer 252, the etch stop layer 242, the capping layer 240 and the passivation layer 210 and contacts the underlying first interconnect structure 206. The bonding interconnect structures 254 may have a T-shape from a cross-sectional view. In some embodiments, the bonding interconnect structures 254 are spaced apart from the barrier liner 222. In some embodiments, the bonding interconnect structures 254 and the barrier liners 222 are not in direct contact.

In some embodiments, the bonding interconnect structures 254 are formed by filling the via-trenches 260 with a conductive material by deposition, sputtering, plating, or a combination thereof. Examples of the conductive material include, but are not limited to, copper, aluminum, an aluminum-copper alloy, and the like. The via-trenches 260 may be over-filled with the conductive material, and a planarization operation (e.g., chemical-mechanical planarization or etch-back processes) may be subsequently performed to remove excess conductive material and thereby form the bonding interconnect structures 254 with a top surface 2542 flush with a top surface 2522 of the bonding dielectric layer 252.

In some embodiments, the first bonding structure 250 may further include diffusion barrier liners 256 formed in the via-trenches 260 prior to the formation of the bonding interconnect structures 254. The diffusion barrier liners 256 may be disposed between the bonding interconnect structures 254 and neighboring dielectric layers (i.e., the passivation layer 210, the capping layer 240, the etch stop layer 242 and the bonding dielectric layer 252). The diffusion barrier liners 256 may further be disposed between the bonding interconnect structures 254 and portions of the topmost conductive lines 2062T. The diffusion barrier liners 256 may serve a function of preventing conductive material in the bonding interconnect structures 254 from diffusing into the neighboring dielectric layers. The diffusion barrier layer 256 may include titanium, titanium nitride, tantalum, tantalum nitride, or the like. The diffusion barrier layer 256 is deposited in the via-trenches 260, for example, using PVD, CVD, ALD, or another suitable method.

Referring to FIG. 16, a second wafer W2 is received in accordance with step S142 in FIG. 1. In some embodiments, the second wafer W2 includes multiple second semiconductor dies 400 that are arranged in column and rows. Scribe streets 401 are provided between every two adjacent second semiconductor dies 400. The second semiconductor dies 400 may include any type of integrated circuit. A functionality provided by the second semiconductor dies 400 may be same as or different from the functionality of the first semiconductor dies 200.

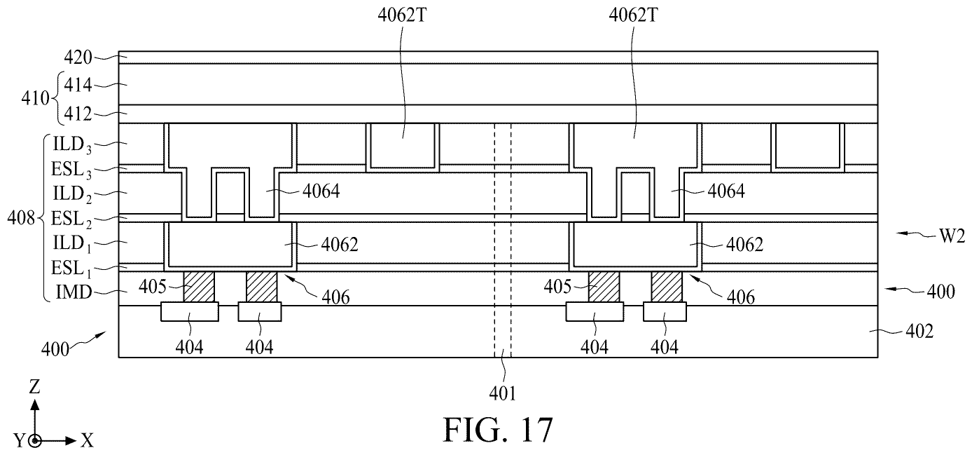

FIG. 17 is a cross-sectional view of a part of the second semiconductor die 400. In some embodiments, the second semiconductor die 400 includes a substrate 402, various semiconductor devices 404, a second interconnect structure 406 and a dielectric stack 408. The semiconductor devices 404 may be disposed in and/or on the substrate 402. The second interconnect structure 406 is disposed over and electrically coupled to the semiconductor devices 404. The second interconnect structure 406 may include alternating conductive lines 4062 and conductive vias 4064 laterally surrounded by the dielectric stack 408. In some embodiments, the materials, configurations and method of forming of the second interconnect structure 406 and the dielectric stack 408 are similar to those of the first interconnect structure 206 and the dielectric stack 208, respectively.

The second interconnect structure 406 may further include conductive liners 4066 between the conductive lines 4062 and the dielectric stack 408, between the conductive vias 4064 and the dielectric stack 408, and between the conductive vias 4064 and underlying conductive lines 4062. The conductive liner 4066 may be formed of titanium, titanium nitride, tantalum, tantalum nitride, or the like. In some embodiments, the second semiconductor die 400 further includes one or more contact plugs 405 used for connecting the semiconductor devices 404 to the second interconnect structure 406. The contact plugs 405 may be disposed between the semiconductor devices 404 and the second interconnect structure 406. The contact plugs 405 may include metal such as tungsten or the like.

The dielectric stack 408 covers the substrate 402 and the semiconductor devices 404 and laterally surrounds the contact plugs 405 and the second interconnect structure 406. The dielectric stack 408 may include an inter-metal layer IMD and a series of inter-layer dielectric layers ILD₁ to ILD₄ and etch stop layers ESL₁ to ESL₃ arranged in an alternating manner. The inter-metal layer IMD may laterally surround the contact plugs 405, and the inter-layer dielectric layers ILD₁ to ILD₄ may laterally surround the second interconnect structure 406. The inter-metal layer includes dielectric material, such as oxide. In some embodiments, the inter-layer dielectric layers ILD₁ to ILD₄ include oxide, and the etch stop layers ESL₁ to ESL₃ include nitride. In FIG. 17, three inter-layer dielectric layers ILD₁ to ILD₃ and three etch stop layers ESL₁ to ESL₃ are shown over the substrate 402 and the semiconductor devices 404, but actual numbers of the inter-layer dielectric layers and the etch stop layers are not limited thereto.

Still referring to FIG. 17, a passivation layer 410 is deposited on the second wafer W2 in accordance with step S144 in FIG. 1. In some embodiments, the passivation layer 410 includes a bottom layer 412 and a top layer 414 sequentially deposited over the second interconnect structure 406 and the dielectric stack 408. The bottom layer 412 may be in contact with the topmost inter-layer dielectric layer ILD₄ and topmost conductive lines 4062T of the second interconnect structure 406. In some embodiments, the bottom layer 412 includes nitride, and the top layer 414 includes oxide.

Next, an etch stop layer 420 is deposited over the passivation layer 410 in accordance with step S146 in FIG. 1. In some embodiments, the etch stop layer 420 covers an entirety of the top layer 414. The etch stop layer 420 is formed of a dielectric material that is different from that of the top layer 414. In some embodiments, the etch stop layer 420 includes nitride. The etch stop layer 420 may be deposited by, for example, CVD, PECVD, the like, or a combination thereof.

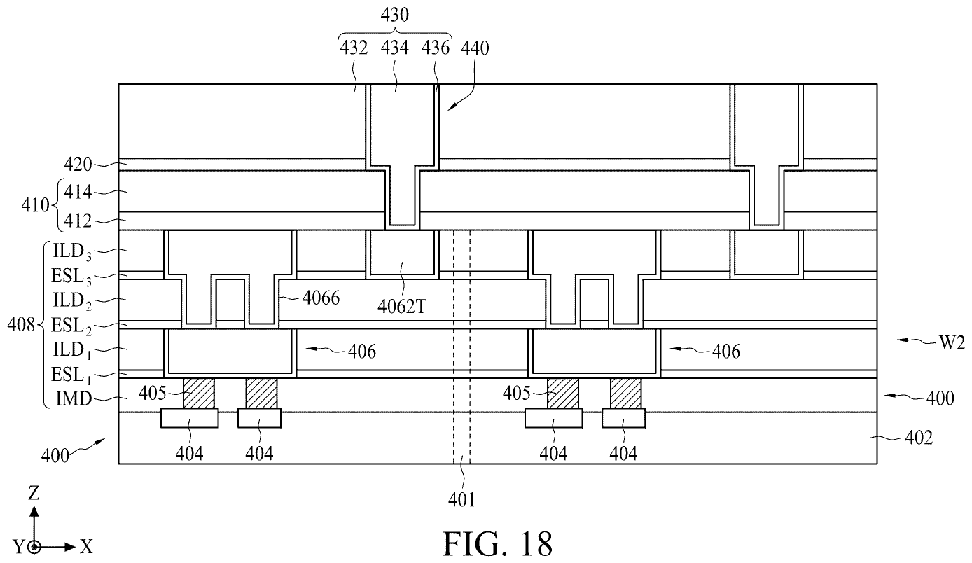

Referring to FIG. 18, a second bonding structure 430 is formed over the second wafer W2 in accordance with step S148 in FIG. 1. The second bonding structure 430 may be similar to the first bonding structure 250. In some embodiments, the second bonding structure 430 is disposed at a front side of the second wafer W2, wherein the front side is where the semiconductor devices 404 are fabricated. The second bonding structure 430 may include a bonding dielectric layer 432 over the etch stop layer 420 and a bonding interconnect structure 434 at least in the bonding dielectric layer 432. In some embodiments, the bonding interconnect structure 434 penetrates through the bonding dielectric layer 432, the etch stop layer 420 and the passivation layer 410 and connects to the underlying second interconnect structure 406, to thereby form an electrical connection with the underlying semiconductor device 404. The forming of the second bonding structure 430 may include depositing the bonding dielectric layer 432 on an entirety of the top surface of the etch stop layer 420 and etching the bonding dielectric layer 432, the etch stop layer 420 and the passivation layer 410 to form via-trenches 440 that expose the topmost conductive lines 4062T. Subsequently, by deposition, sputtering, plating, or combinations thereof, the via-trenches 440 are filled with a conductive material to form the bonding interconnect structure 434.

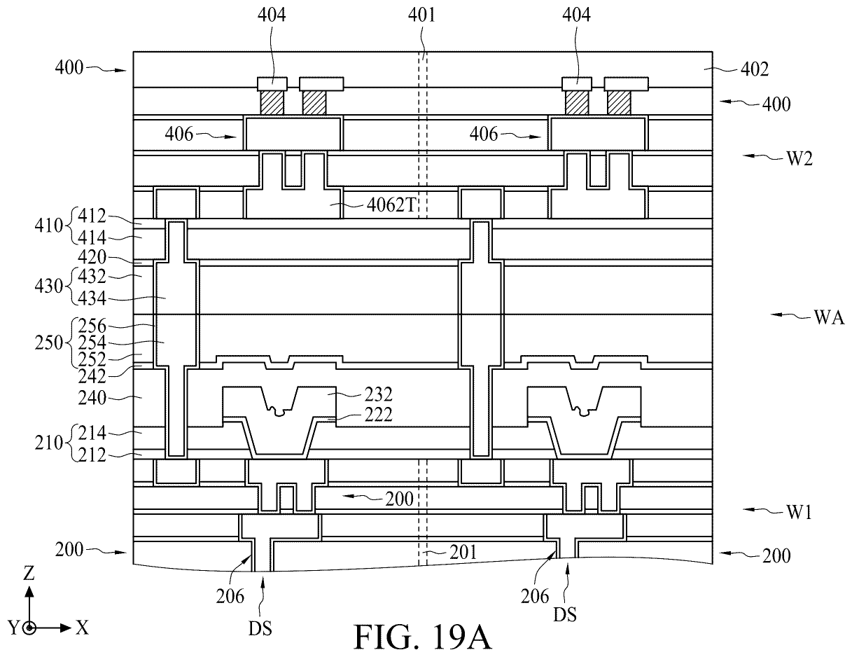

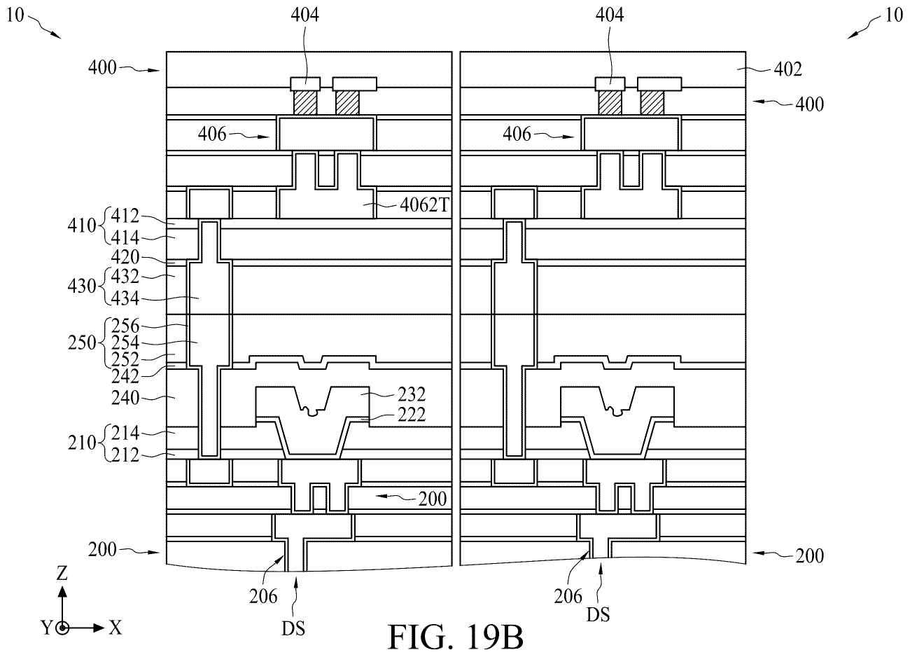

Referring to FIG. 19A, the first wafer W1 and the second wafer W2 are bonded to form a wafer assembly WA in accordance with step S162 in FIG. 1. In some embodiments, the first wafer W1 and the second wafer W2 are front-to-front bonded together through the first bonding structure 250 and the second bonding structure 430. During the bonding operation, the second wafer W2 is flipped, i.e., rotated 180 degrees, from an orientation shown in FIG. 18 and positioned over the first wafer W1. Therefore, a front side of the first wafer W1 faces a front side of the second wafer W2. Subsequently, the bonding interconnect structures 434 over the second wafer W2 are aligned with the bonding interconnect structures 254 over the first wafer W1. After the alignment, a bonding force may be applied to the second wafer W2 to press the second wafer W2 against the first wafer W1. As a result, the bonding dielectric layer 432 is in contact with the bonding dielectric layer 252, and the bonding interconnect structures 434 are respectively in contact with the bonding interconnect structures 254.

The bonding of the first wafer W1 to the second wafer W2 may be achieved through hybrid bonding. In the hybrid bonding, the bonding interconnect structures 434 over the second wafer W2 are bonded to the bonding interconnect structures 254 over the first wafer W1 through a metal-to-metal bonding. In addition, the bonding dielectric layer 432 over the second wafer W2 is bonded to the bonding dielectric layer 252 over the first wafer W1 through dielectric-to-dielectric bonding, such as a fusion operation. After the hybrid operation, each first semiconductor die 200 may be electrically coupled to the overlying second semiconductor die 400 by the bonding of the interconnect structures 254 and 434 disposed therebetween. The first die 200, the barrier liner 222 and the test pad 232 connected to the first die 200, the second die 400 overlying and aligned with the first die 200, parts of the first and second bonding structures 250 and 430 between the first and second dies 200 and 400, and portions of the passivation layers 210 and 410, the capping layer 240, and the etch stop layers 242 and 420 between the first and second dies 200 and 400 are in combination referred to as a die stack DS. According to some embodiments, only one of the semiconductor dies 200 and 400, e.g., the first semiconductor die 200, is subject to the pre-bonding testing operation before they are bonded to form the wafer assembly WA.

After the wafer assembly WA is completely formed, a test is performed on the wafer assembly WA in accordance with step S164 in FIG. 1. The test may be performed to determine a functionality of the die stacks DS in the wafer assembly WA. The test of the die stacks DS is referred to as a die stack test. In some embodiments, a plurality of through substrate vias (not shown) are formed in the die stacks DS in the wafer assembly WA prior to the test. The through substrate vias may be formed in the first and second wafers W1 and W2 and electrically coupled to the first and second interconnect structures 206 and 406. The test may be performed by coupling the die stacks DS in the wafer assembly WA to a testing apparatus (not shown) through the through substrate vias.

The test apparatus may be operable to perform one or more wafer-level tests to determine performance and reliability of the die stacks DS under various conditions. The test apparatus may be further operable to identify good die stacks and defective die stacks in the wafer assembly WA. In some embodiments, a die stack DS that successfully meets a test specification or has passed all of the wafer-level tests is identified as a known good die stack, and a die stack DS that fails to meet the test specification or fails the test procedure is identified as a defective die stack. The defective die stack may be marked to be excluded from a packaging operation after a die-saw operation. Thus, packaging costs can be saved. A die stack DS that includes a marked first semiconductor die 200 (i.e., a defective die) may fail the test procedure in the die stack test. The die stack DS that includes a non-marked first semiconductor die 200 (i.e., a known good die) may fail the test procedure in the die stack test when the second semiconductor die is defective.

After the test is completed, the die-saw operation is performed on the wafer assembly WA in accordance with step S166 in FIG. 1. Consequently, a plurality of semiconductor die assemblies 10, as shown in FIG. 19B, are completely formed. Referring to FIGS. 19A and 19B, the die-saw operation may be performed by sawing along the scribe streets 201 and 401 of the first and second wafers W1 and W2 to separate the individual die stacks DS from the wafer assembly WA. The bonding pads 232 may be left in the die stack DS after the die-saw operation. Each semiconductor die assembly 10 may include the individual die stack DS. For example, each semiconductor die assembly 10 may include a first die 200, a barrier liner 222 and a test pad 232 connected to the first die 200, a second die 400 vertically stacked on the first die 200, parts of the first and second bonding structures 250 and 430, the passivation layers 210 and 410, the capping layer 240, and the etch step layers 242 and 420 between the first die 200 and the second die 400.

After the die-saw operation, the good die stacks are packaged, and the defective die stacks may be discarded, and hence additional cost and effort are not wasted on the defective die stacks.

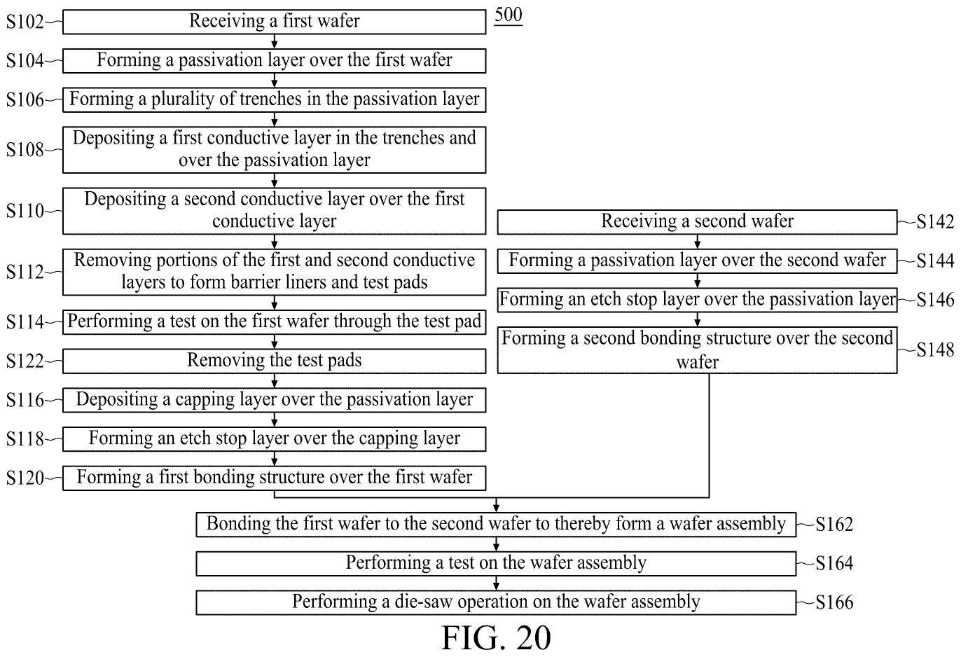

FIG. 20 is a flowchart of a method 500 of manufacturing a semiconductor die assembly, in accordance with some embodiments of the present disclosure. The method 500 in FIG. 20 is similar to the method 100 in FIG. 1 except the method 500 further includes step S122 between steps S114 and S116. Similar reference numbers in FIG. 1 and FIG. 20 indicate similar steps, procedures or features.

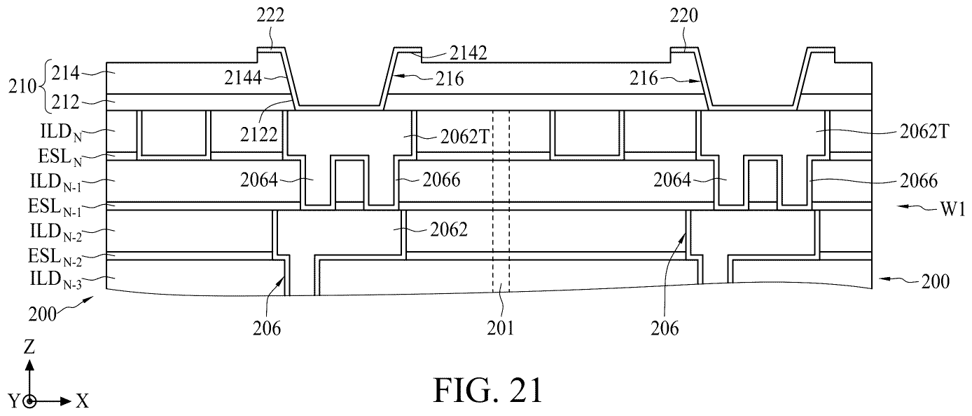

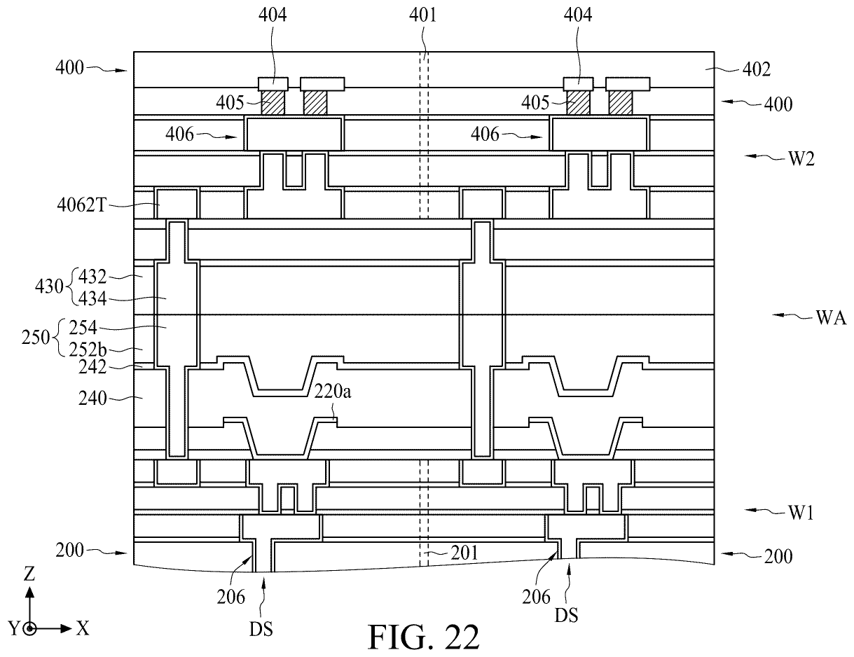

In step S122, the test pads 232 are removed, as shown in FIG. 21. The test pads 232 may be removed by an etching operation, such as a wet etch. However, the present disclosure is not limited thereto, and the test pads 232 may be removed using other suitable techniques. After the removal of the test pads 232, the barrier liners 222 are exposed. Accordingly, the subsequently-formed capping layer 240 is conformal to the top layer 214 and the barrier liners 222, as shown in FIG. 22. The capping layer 240 and thus the die stacks DS may have a reduced thickness as compared to the capping layer 240 of the die stack DS shown in FIG. 19A due to the removal of the test pads 232.

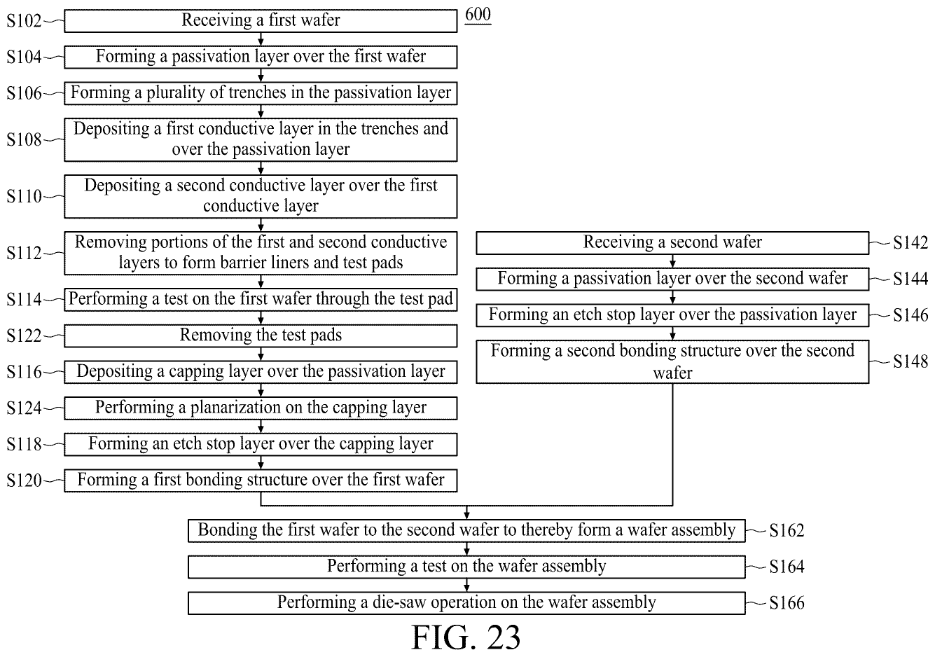

FIG. 23 is a flowchart of a method 600 of manufacturing a semiconductor die assembly, in accordance with some embodiments of the present disclosure. The method 600 in FIG. 23 is similar to the method 500 in FIG. 20 except the method 600 further includes step S124 between steps S116 and S118. Similar reference numbers in FIG. 20 and FIG. 23 indicate similar steps, procedures or features.

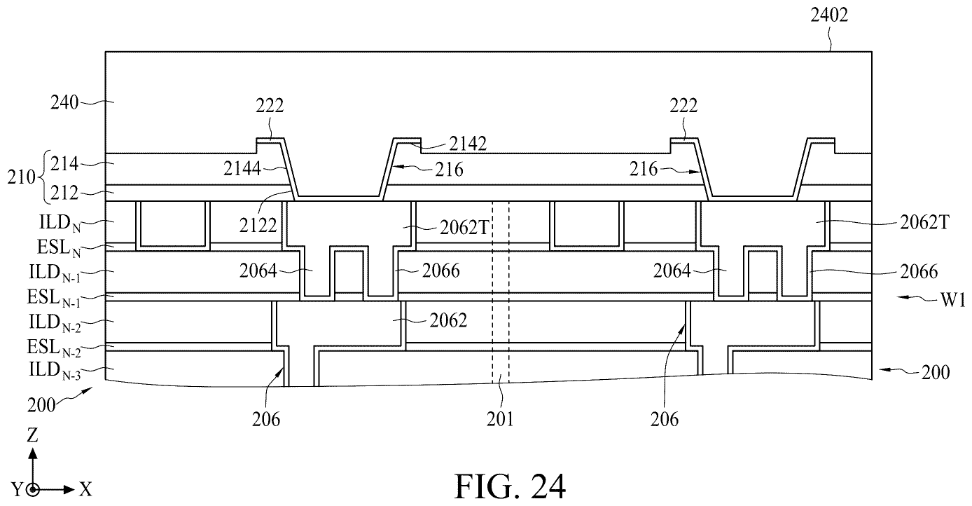

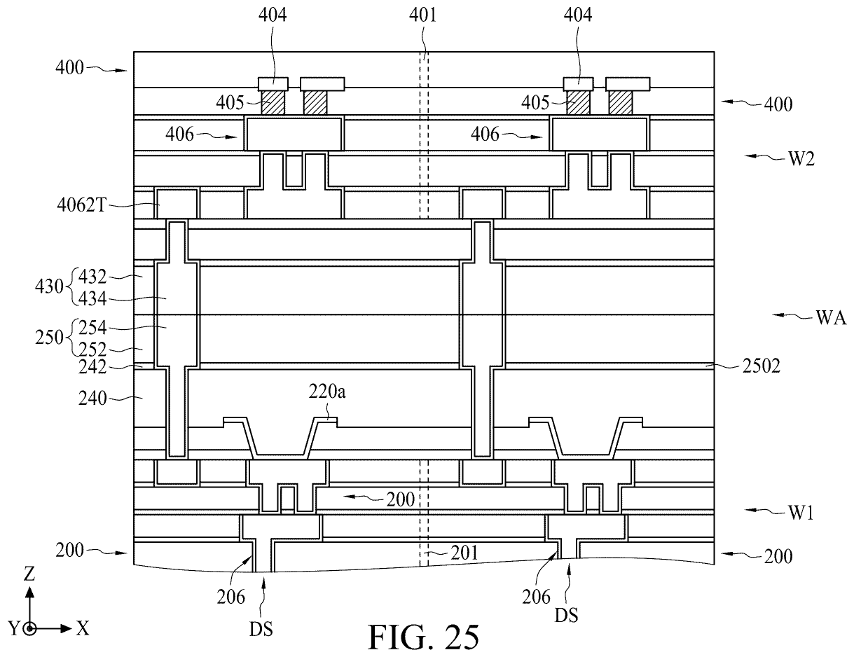

In step S124, a planarization operation is performed on the capping layer 240, as shown in FIG. 24. The planarization operation may include, for example, a CMP operation, a grinding operation, an etching operation, the like, or a combination thereof. After the planarization operation, the capping layer 240 has a substantially planar top surface 2402. According, the subsequently-formed etch stop layer 250 also has a substantially planar lower surface 2502, as shown in FIG. 25.

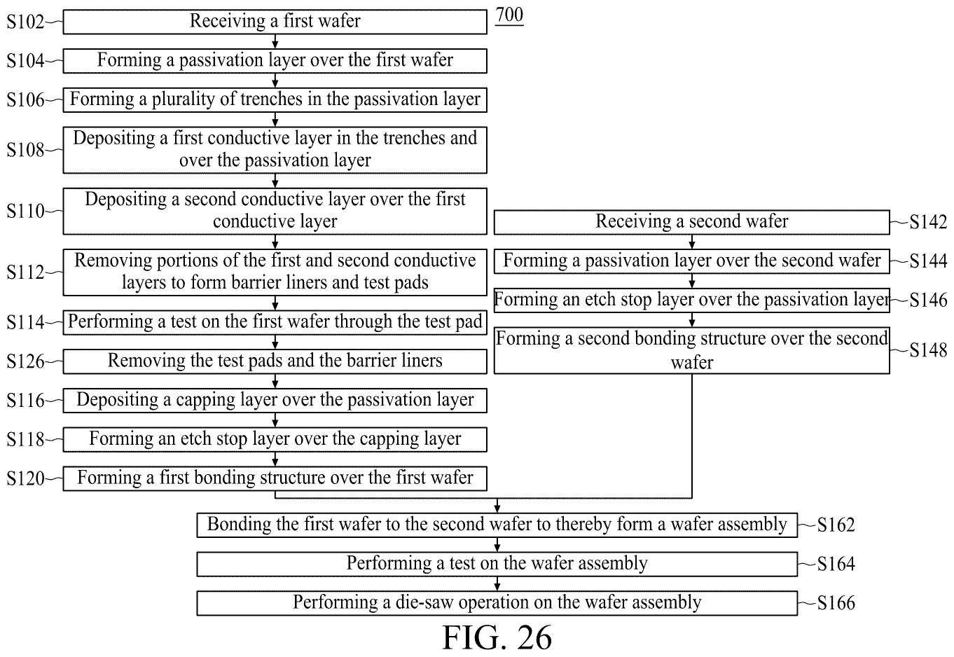

FIG. 26 is a flowchart of a method 700 of manufacturing a semiconductor die assembly, in accordance with some embodiments of the present disclosure. The method 700 in FIG. 26 is similar to the method 100 in FIG. 1 except the method 700 further includes step S126 between steps S114 and S116. Similar reference numbers in FIG. 1 and FIG. 26 indicate similar steps, procedures or features.

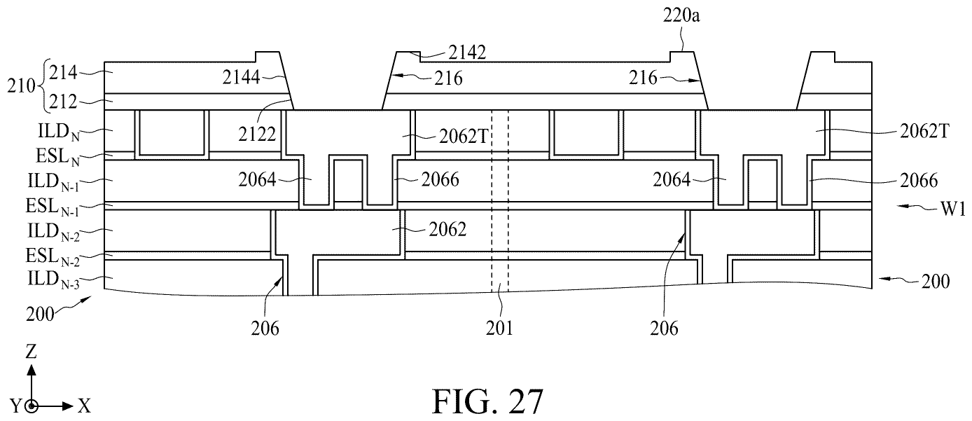

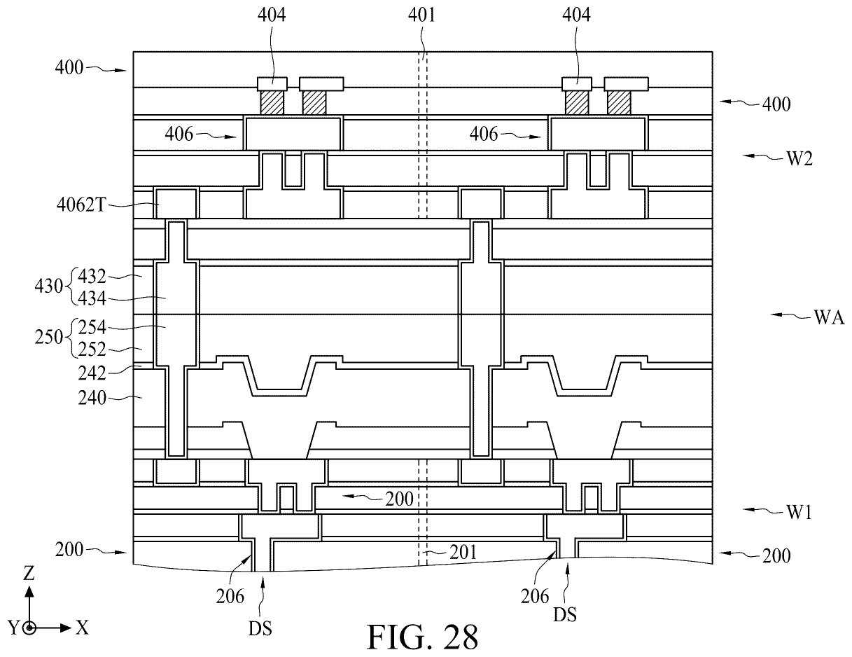

In step S126, the test pads 232 and the barrier liners 222 are removed, as shown in FIG. 27. The test pads 232 and the barrier liners 222 may be removed by one or more etching operations or other suitable techniques. After the removal of the test pads 232 and the barrier liners 222, portions of the topmost conductive lines 2062T are exposed. Accordingly, the subsequently-formed capping layer 240 is conformal to the top layer 214 and the portions of the topmost conductive lines 2062T, as shown in FIG. 28. The capping layer 240 and thus the die stacks DS may have a reduced thickness as compared to the capping layer 240 of the die stack DS shown in FIG. 19A due to the removal of the barrier liners 222 and the test pads 232.

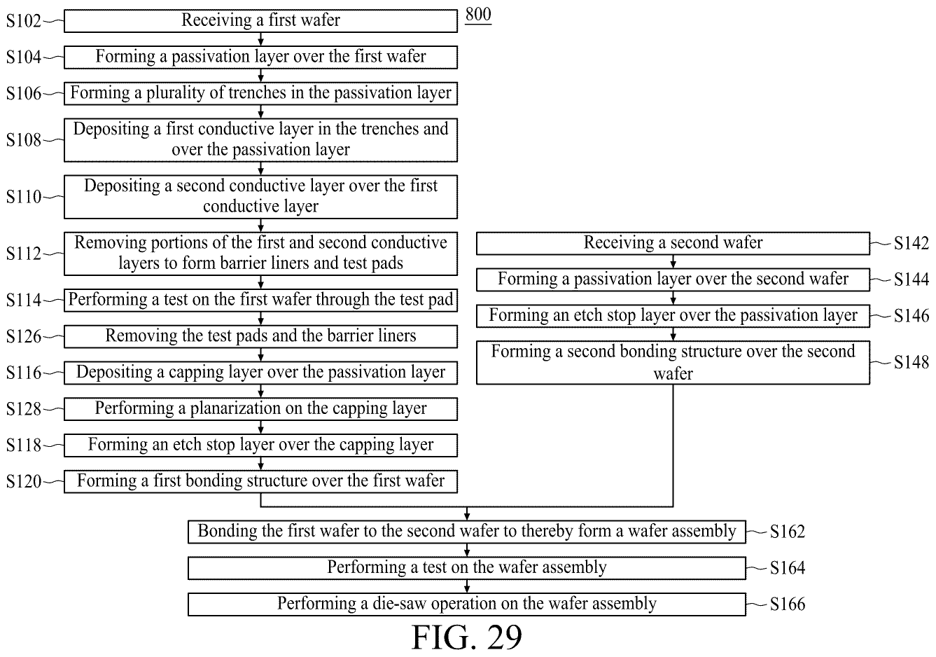

FIG. 29 is a flowchart of a method 800 of manufacturing a semiconductor die assembly, in accordance with some embodiments of the present disclosure. The method 800 in FIG. 29 is similar to the method 700 in FIG. 26 except the method 800 further includes step S128 between steps S116 and S118. Similar reference numbers in FIG. 26 and FIG. 29 indicate similar steps, procedures or features.

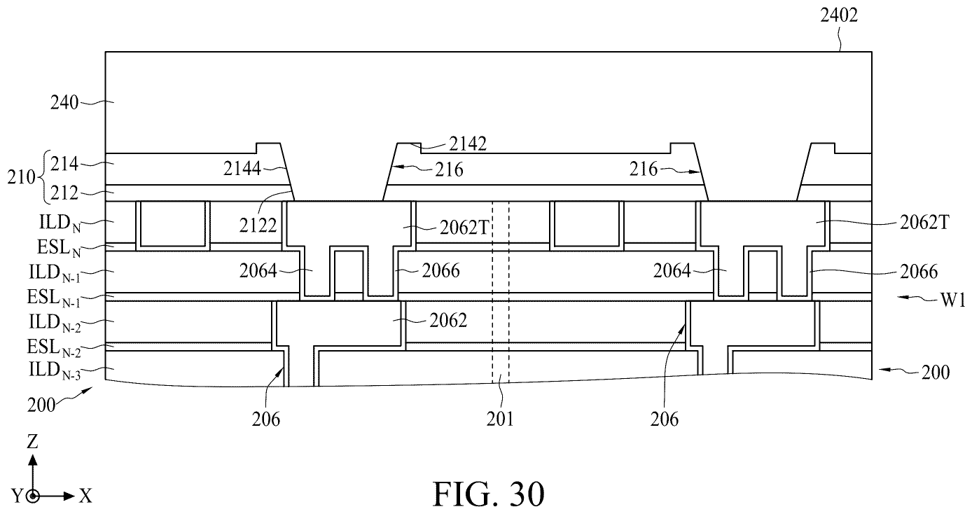

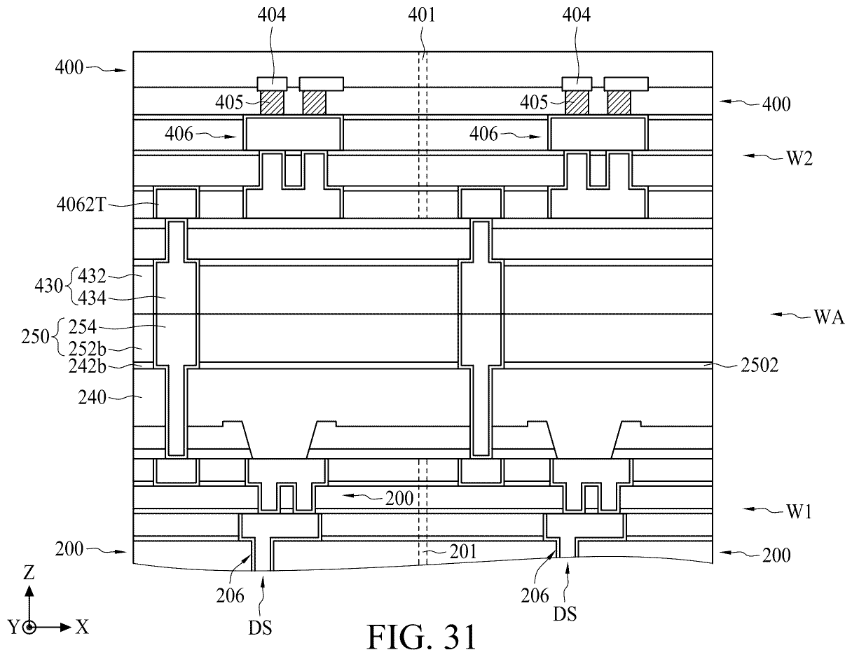

In step S128, a planarization operation is performed on the capping layer 240, as shown in FIG. 30. The planarization operation may include, for example, a CMP operation, a grinding operation, an etching operation, the like, or a combination thereof. After the planarization operation, the capping layer 240 has a substantially planar top surface 2402. According, the subsequently-formed etch stop layer 250 also has a substantially planar lower surface 2502, as shown in FIG. 31.

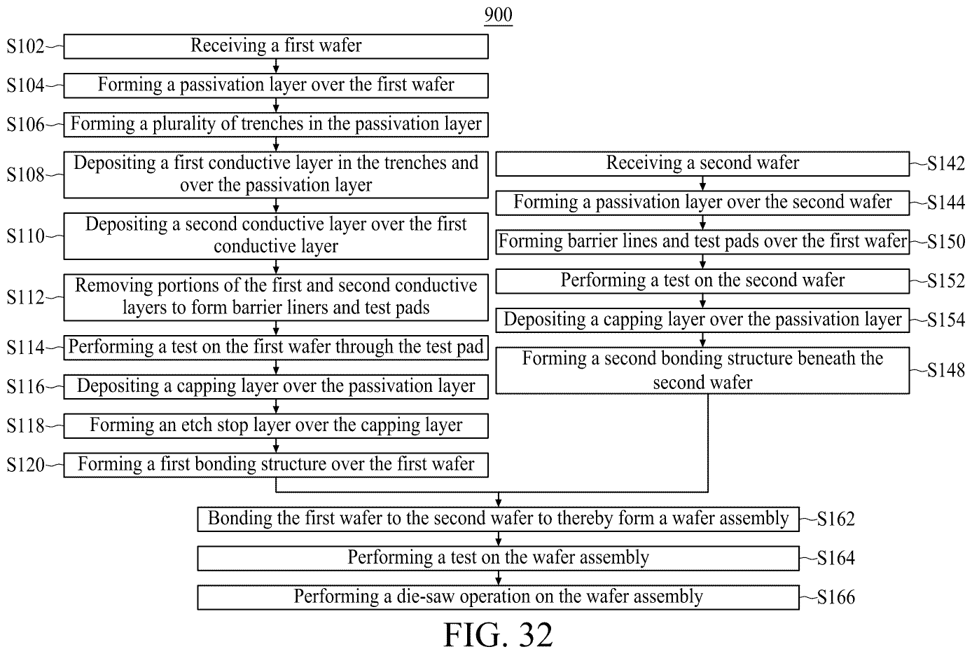

FIG. 32 is a flowchart of a method 900 of manufacturing a semiconductor die assembly, in accordance with some embodiments of the present disclosure. The method 900 in FIG. 32 is similar to the method 100 in FIG. 1 except the method 900 further includes steps S150, S152 and S154 between steps S144 and S148. Similar reference numbers in FIG. 1 and FIG. 32 indicate similar steps, procedures or features.

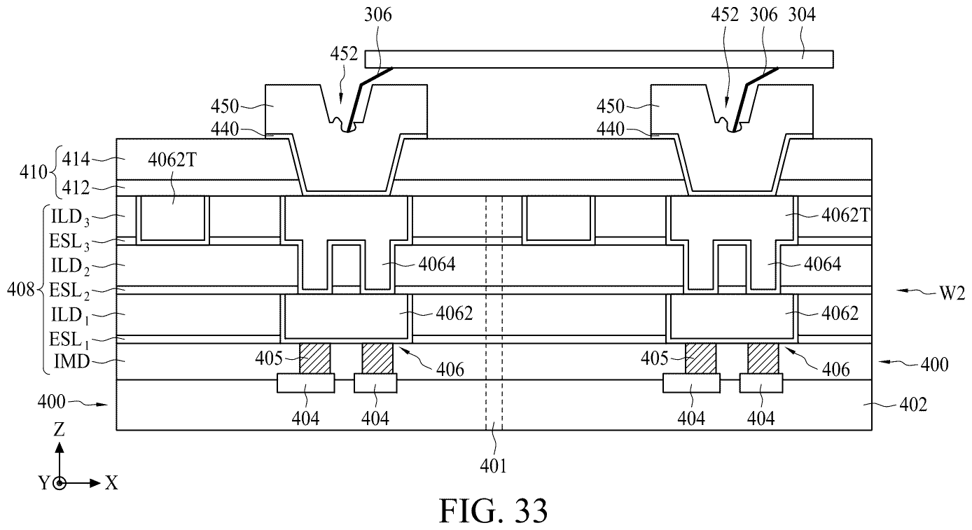

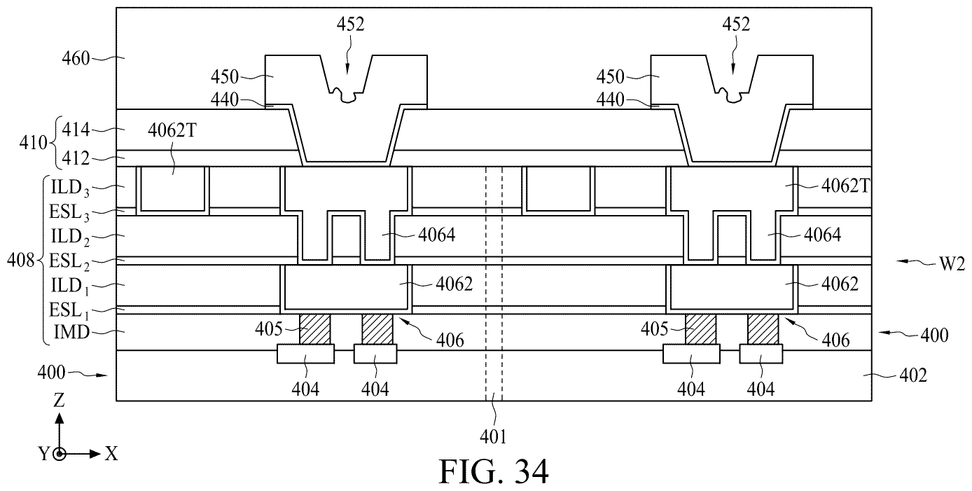

Referring to FIGS. 32 and 33, in step S150, barrier liners 440 and test pads 450 are formed over the second wafer W2. In some embodiments, the barrier liners 440 and the test pads 450 are formed in and over the passivation layer 410. Each barrier liner 440 may separate the test pad 450 from the passivation layer 410. The barrier liner 440 may be configured to prevent diffusion of metal atoms from the test pad 450 to the passivation layer 410. The barrier liner 440 may also separate the test pad 450 from the topmost conductive line 4062T. The barrier liner 440 and the test pad 450 may be formed to penetrate the passivation layer 410 by one or more etching operations to form trenches that expose portions of the topmost conductive line 4062T, subsequently forming a barrier layer and a conductive layer, and then patterning the barrier layer and the conductive layer. The etching operations and the patterning of the barrier layer and the conductive layer each may include a wet etch, a dry etch, a combination thereof, or the like. In some embodiments, a thickness of the top layer 414 may remain unchanged by the etching operations. However, the present disclosure is not limited thereto, and portions of the top layer 414 not covered by the barrier liners 440 and the test pads 450 may have a reduced thickness. The barrier layer may be formed, for example, by PVD, CVA, ALD or another suitable technique. The second conductive layer 230 may be formed, for example, by sputtering, CVD, PVD, ALD, or another suitable technique. In some embodiments, the diffusion barrier liner 440 includes titanium, titanium nitride, tantalum or tantalum nitride. The test pad 450 may include a conductive material, such as copper, aluminum, an aluminum-copper alloy, or the like.

Still referring to FIG. 33, the method proceeds to step S152, in which a test is performed on the second wafer W2 through the test pads 450. In some embodiments, the second test is performed on all second semiconductor dies 400 on the second wafer W2. The second test may be performed by using a testing apparatus 304 that includes a plurality of testing probes 306. The testing apparatus 304 and the testing probes 306 may be similar to those described above with reference to FIG. 8. The test is performed by aligning each testing probe 306 and a corresponding test pad 450 above the second wafer W2 and then pushing the test probe 306 against the corresponding test pad 450 with a force in order to couple the test probe 306 to the test pad 450. As a result, probe marks 452 are formed by the testing probe 306.

The testing apparatus 304 is configured to send test signals and receive test results to and from the second semiconductor devices 400 via the testing probes 306 and the test pads 450. The test results may include information with respect to the second semiconductor devices 400. The testing apparatus 304 may be further configured to analyze the test results to determine whether the second semiconductor dies 400 meet a test specification. In some embodiments, a second semiconductor die 400 that meets the test specification is identified as a known good die, and a second semiconductor die 400 that fails to meet the test specification is determined to be a defective die.

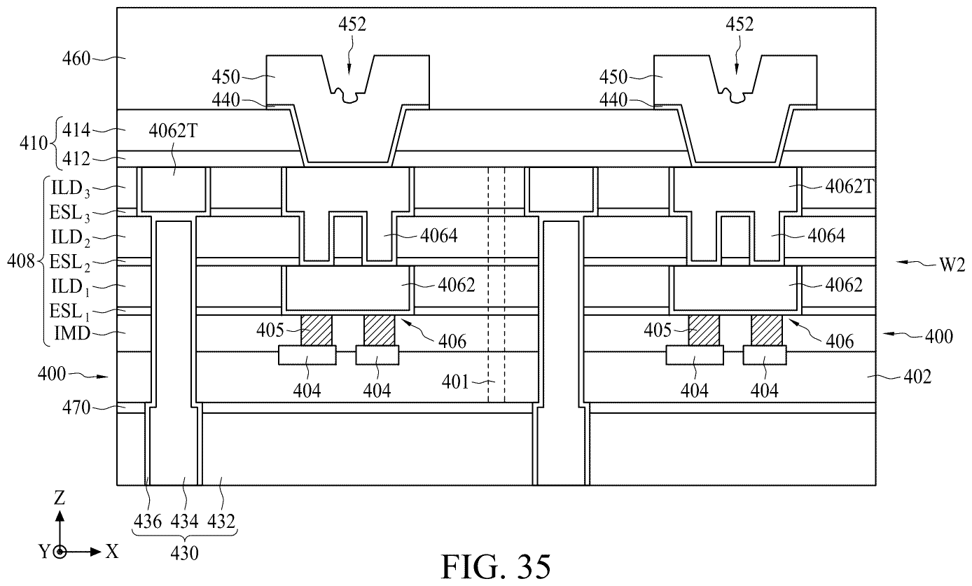

After the test is completed, the method proceeds to step S154, in which a capping layer 460 is deposited over the passivation layer 410 and the test pads 450, as shown in FIG. 35. In some embodiments, the capping layer 460 is conformal to the top layer 414, the barrier liners 440 and the test pads 450. The capping layer 460 may include oxide. The capping layer 460 may be formed by any suitable method, such as CVD, a spin-coating operation, a combination thereof, or the like.

Still referring to FIG. 35, in some embodiments, the second bonding structure 430 formed in step S148 is at a back side of the second wafer W2. The back side of the second wafer W2 may be a side free of the semiconductor devices 404. The second bonding structure 430 may include a bonding dielectric layer 432 disposed beneath the second substrate 402 and a bonding interconnect structure 434 disposed at least in the bonding dielectric layer 432. In some embodiments, the bonding dielectric layer 432 is disposed on and conformal to a lower surface 4022 of the second substrate 402. The bonding interconnect structure 434 may penetrate the bonding dielectric layer 432 and the dielectric stack 408 and is electrically coupled to the second interconnect structure 406.

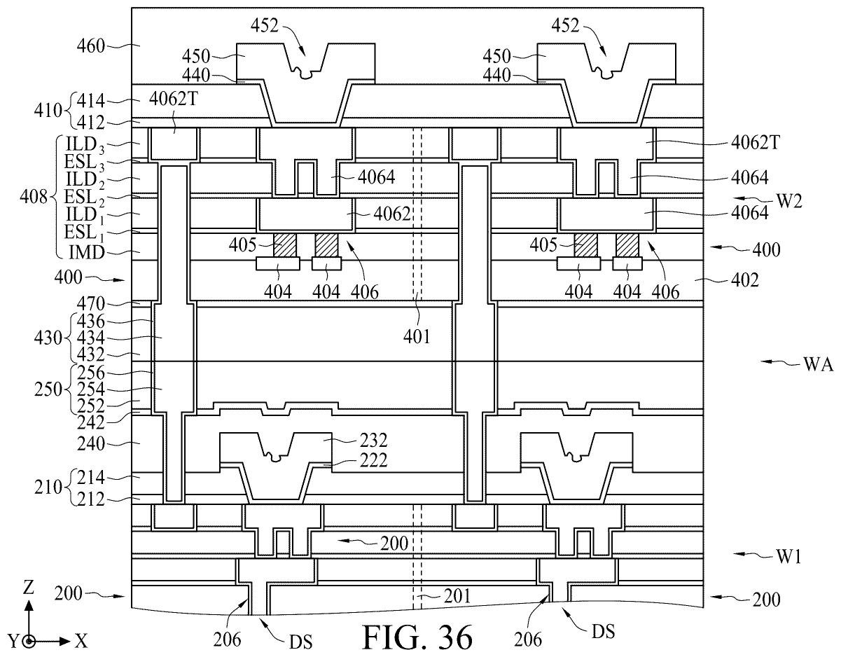

During the bonding of the first wafer W1 to the second wafer W2 (i.e., step S162 in FIG. 32), the second wafer W2 is positioned on the first wafer W1, and the front side of the first wafer W1 faces the back side of the second wafer W2 to thereby form a front-to-back arrangement. Therefore, the first wafer W1 and the second wafer W2 are bonded through a front-to-back bonding, as shown in FIG. 36. The first wafer W1 and the second wafer W2 may be also bonded, for example, through a back-to-back bonding or a back-to-front bonding.

In accordance with some embodiments of the present disclosure, a method of manufacturing a semiconductor die assembly includes steps of receiving a first wafer comprising a first semiconductor device and a first interconnect structure disposed over and electrically coupled to the first semiconductor device; forming a first passivation layer over the first interconnect structure; forming a first barrier layer in the first passivation layer; forming a first test pad on the first barrier layer; performing a first test on the first semiconductor device through the first test pad; forming a first bonding structure over the first passivation layer and the first barrier layer; receiving a second wafer comprising a second semiconductor device and a second interconnect structure electrically coupled to the second semiconductor device; forming a second bonding structure over the second interconnect structure; bonding the first wafer to the second wafer by connecting the first bonding structure and the second bonding structure to form a wafer assembly; and performing a second test on the wafer assembly.

In accordance with some embodiments of the present disclosure, a method of manufacturing a semiconductor die assembly includes steps of forming a passivation layer on a first wafer comprising an interconnect structure; depositing a first conductive layer in and over the passivation layer; removing portions of the first conductive layer offset from the portion of the interconnect structure to form a test pad over the portion of the interconnect structure; performing a first test on the first wafer through the test pad; removing the test pad in response to the first wafer meeting a test specification of the first test; forming a first bonding structure over the passivation layer; forming a second bonding structure over a second wafer; bonding the first wafer to the second wafer by connecting the first bonding structure and the second bonding structure to form a wafer assembly; and performing a second test on the wafer assembly.

In accordance with some embodiments of the present disclosure, a semiconductor die stack includes a first die comprising a first semiconductor device and a first interconnect structure disposed over the first semiconductor device; a passivation layer covering the first interconnect structure; a barrier liner laterally surrounded by the passivation layer and in contact with the first interconnect structure; a bonding structure disposed over the passivation layer and the barrier liner; and a second die disposed on the bonding structure and comprising a second semiconductor device and a second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor die assembly, comprising:
receiving a first wafer comprising a first semiconductor device and a first interconnect structure disposed over and electrically coupled to the first semiconductor device;
forming a first barrier liner on a portion of the first interconnect structure;
forming a first test pad on the first barrier liner;
performing a first test on the first semiconductor device through the first test pad;
forming a first bonding structure over the first interconnect structure;
receiving a second wafer comprising a second semiconductor device and a second interconnect structure electrically over and coupled to the second semiconductor device;
forming a second bonding structure over the second interconnect structure;
bonding the first wafer to the second wafer by connecting the first bonding structure and the second bonding structure to form a wafer assembly; and
performing a second test on the wafer assembly.

2. The method of claim 1, further comprising, prior to the forming of the first bonding structure:
depositing a first passivation layer covering the first wafer, wherein the first barrier liner and the first test pad are partially and laterally surrounded by the first passivation layer; and
depositing a first capping layer over the first passivation layer, the first barrier liner and the first test pad, wherein the first capping layer is conformal to the first passivation layer, the first barrier liner and the first test pad.

3. The method of claim 2, further comprising performing a planarization operation on the first capping layer, wherein after the planarization operation, the first capping layer has a planar top surface.

4. The method of claim 1, further comprising, prior to the forming of the second bonding structure on the second wafer:
depositing a second passivation layer over the second interconnect structure;
forming a second barrier liner in the second passivation layer;
forming a second test pad on the second barrier liner; and
performing a third test on the second semiconductor device through the second test pad.

5. The method of claim 4, further comprising, subsequent to the performing of the third test and prior to the forming of the second bonding structure over the second wafer:
depositing a second capping layer over the second passivation layer and the second test pad, wherein the second capping layer is conformal to the second passivation layer, the second barrier liner and the second test pad.

6. The method of claim 4, further comprising, subsequent to the performing of the third test and prior to the forming of the second bonding structure over the second wafer:
removing the second test pad; and
depositing a second capping layer over the second passivation layer and the second barrier liner, wherein the second capping layer is conformal to the second passivation layer and the second barrier liner.

7. The method of claim 6, further comprising performing a planarization operation on the second capping layer, wherein after the planarization operation, the second capping layer has a planar top surface.

8. The method of claim 4, further comprising, subsequent to the third test and prior to the forming of the second bonding structure over the second wafer:
removing the second test pad and the second barrier liner; and
depositing a second capping layer over the second passivation layer and the second interconnect structure, wherein the second capping layer is conformal to the second passivation layer and a portion of the second interconnect structure exposed through the second passivation layer.

9. The method of claim 8, further comprising performing a planarization operation on the second capping layer, wherein after the planarization operation, the second capping layer has a planar top surface.

10. The method of claim 1, wherein the bonding of the first wafer to the second wafer comprises dielectric-to-dielectric bonding and metal-to-metal bonding.

11. The method of claim 1, wherein the first wafer and the second wafer are bonded through a front-to-front bonding.

12. The method of claim 1, wherein the first wafer and the second wafer are bonded through a front-to-back bonding.

13. A method of manufacturing a semiconductor die assembly, comprising:
forming a passivation layer on a first wafer comprising an interconnect structure;
depositing a first conductive layer in and over the passivation layer;
removing portions of the first conductive layer to form a test pad over the portion of the interconnect structure;
performing a first test on the first wafer through the test pad;
removing the test pad in response to the first wafer meeting a test specification of the first test;
forming a first bonding structure over the passivation layer;
forming a second bonding structure over a second wafer;
bonding the first wafer to the second wafer by connecting the first bonding structure and the second bonding structure to form a wafer assembly; and
performing a second test on the wafer assembly.

14. The method of claim 13, wherein the first wafer and the second wafer are bonded through hybrid bonding.

15. The method of claim 13, further comprising depositing a capping layer conformal to the passivation layer prior to the forming of the first bonding structure.

16. The method of claim 15, further comprising performing a planarization operation on the capping layer, wherein after the planarization operation, the capping layer has a planar top surface.

17. The method of claim 13, wherein the forming of the first bonding structure comprises:
depositing a bonding dielectric layer over the passivation layer;
etching the bonding dielectric layer and the passivation layer to form a via-hole exposing a portion of the interconnect structure;
etching the bonding dielectric layer to form a second trench connected to the via-hole; and
depositing a conductive material in the via-hole and the second trench to form a bonding interconnect structure in the bonding dielectric layer and the passivation layer.

18. A semiconductor die assembly, comprising:
a first die comprising a first semiconductor device and a first interconnect structure disposed over the first semiconductor device;
a passivation layer covering the first interconnect structure;
a barrier liner laterally surrounded by the passivation layer and in contact with the first interconnect structure;
a bonding structure disposed over the passivation layer and the barrier liner; and
a second die disposed on the bonding structure and comprising a second semiconductor device and a second interconnect structure.

19. The semiconductor die assembly of claim 18, further comprises a test pad arranged above the barrier liner.

20. The semiconductor die assembly of claim 19, wherein the test pad has a roughened top surface.
